(19) United States
(12) Patent Application Publication
(10) Pub. No.: US 2023/0144766 A1
(43) Pub. Date: May 11, 2023

(54) DISPLAY DEVICE INCLUDING A LIGHT CONTROL LAYER AND MANUFACTURING METHOD OF THE SAME

(71) Applicant: Samsung Display Co., Ltd., Yongin-si (KR)

(72) Inventors: WOONGSIK KIM, Seoul (KR); DONGWAN BAE, Seoul (KR); JEONGWON KIM, Hwaseong-si (KR); JUNGI KIM, Hwaseong-si (KR); JIN-SU BYUN, Seoul (KR)

(21) Appl. No.: 17/887,007

(22) Filed: Aug. 12, 2022

(30) Foreign Application Priority Data
Nov. 8, 2021 (KR) 10-2021-0152113

(51) Int. Cl. H01L 27/32; H01L 51/52; H01L 51/56

(52) U.S. Cl. CPC H01L 27/3246; H01L 51/5284; H01L 51/5275; H01L 51/5237; H01L 51/56; H01L 2227/323

(57) ABSTRACT

A display device includes: a display panel including a pixel defining film and a light-emitting element, wherein the pixel defining film includes a pixel opening, wherein the light-emitting element includes a first electrode, a light-emitting layer, and a second electrode, and wherein the first electrode is at least partially exposed through the pixel opening; and a light control layer including a pattern layer and a cover layer, wherein the pattern layer overlaps the pixel opening, and wherein the cover layer covers the pattern layer and has a refractive index lower than that of the pattern layer, wherein: the pattern layer includes an upper surface, a lower surface opposite to the upper surface, and a side surface connecting the upper surface and the lower surface to each other, and an angle between the side surface and the lower surface is an acute angle.

### CROSS-REFERENCE TO RELATED APPLICATION

This U.S. non-provisional patent application claims priority under 35 U.S.C. § 119 of Korean Patent Application No. 10-2021-0152113, filed on Nov. 8, 2021, the disclosure of which is incorporated by reference herein in its entirety.

### TECHNICAL FIELD

The present inventive concept relates to a display device and a method of manufacturing the same, and more particularly, to a display device including a light control layer and a method of manufacturing the same.

### DISCUSSION OF THE RELATED ART

Various display devices used in multimedia devices such as televisions, mobile phones, tablets, computers, and game machines are currently under development. Generally, a display device may include various optical functional layers to provide a relatively high-quality color image to a user.

In addition, to realize various types of display devices such as a display device including a curved surface, a rollable display device, and a foldable display device, studies on display devices to further develop them to be thinner have been conducted in recent years.

### SUMMARY

The present inventive concept provides a display device including a light control layer configured to increase light efficiency and reduce the reflection of external light.

The present inventive concept also provides a simplified manufacturing process of the light control layer to reduce processing time and cost.

According to an embodiment of the present inventive concept, a display device includes: a display panel including a pixel defining film and a light-emitting element, wherein the pixel defining film includes a pixel opening, wherein the light-emitting element includes a first electrode, a light-emitting layer, and a second electrode, and wherein the first electrode is at least partially exposed through the pixel opening; and a light control layer including a pattern layer and a cover layer, wherein the pattern layer overlaps the pixel opening, and wherein the cover layer covers the pattern layer and has a refractive index lower than that of the pattern layer, wherein: the pattern layer includes an upper surface, a lower surface opposite to the upper surface and more adjacent to the display panel than the upper surface, and a side surface connecting the upper surface and the lower surface to each other, and an angle between the side surface and the lower surface is an acute angle.

In an embodiment of the present inventive concept, at a portion of the pattern layer at which a thickness from the lower surface to the side surface of the pattern layer is about ⅓ of a maximum thickness of the pattern layer, and wherein the angle formed by the lower surface with respect to a tangential direction of the side surface is about 65 degrees or less.

In an embodiment of the present inventive concept, a maximum thickness of the pattern layer is about 1.5 micrometers to about 3.5 micrometers.

In an embodiment of the present inventive concept, the pixel opening includes a first pixel opening, a second pixel opening, and a third pixel opening which have different areas from each other, and the pattern layer includes a first pattern corresponding to the first pixel opening, a second pattern corresponding to the second pixel opening, and a third pattern corresponding to the third pixel opening.

In an embodiment of the present inventive concept, on a plane, a distance between an edge of each of the first to third patterns and an edge of a corresponding pixel opening among the first to third pixel openings is about 0.5 micrometers or more.

In an embodiment of the present inventive concept, on a plane, a distance between an edge of the first pattern and an edge of the first pixel opening, a distance between an edge of the second pattern and an edge of the second pixel opening, and a distance between an edge of the third pattern and an edge of the third pixel are different from one another.

In an embodiment of the present inventive concept, the display device further includes an input sensor disposed between the display panel and the light control layer, wherein the display panel further includes an encapsulation layer disposed on the light-emitting element, wherein the input sensor includes a first insulating layer, a first conductive layer, a second insulating layer, a second conductive layer, and a third insulating layer, wherein the first insulating layer is disposed on the encapsulation layer, wherein the first conductive layer is disposed on the first insulating layer, wherein the second insulating layer is disposed on the first insulating layer and covers the first conductive layer, wherein the second conductive layer is disposed on the second insulating layer, and wherein the third insulating layer is disposed on the second insulating layer and covers the second conductive layer, and wherein the light control layer is disposed on the third insulating layer.

In an embodiment of the present inventive concept, the display device further includes an input sensor disposed between the display panel and the light control layer, wherein the display panel further includes an encapsulation layer disposed on the light-emitting element, wherein the input sensor includes a first insulating layer, a first conductive layer, a second insulating layer, and a second conductive layer, wherein the first insulating layer is disposed on the encapsulation layer, wherein the first conductive layer is disposed on the first insulating layer, wherein the second insulating layer is disposed on the first insulating layer and covers the first conductive layer, and wherein the second conductive layer is disposed on the second insulating layer, and wherein the light control layer is disposed on the second insulating layer.

In an embodiment of the present inventive concept, the pattern layer covers at least a portion of the second conductive layer.

In an embodiment of the present inventive concept, the light control layer further includes a light blocking pattern covering the second conductive layer.

In an embodiment of the present inventive concept, the display device further includes a light blocking pattern disposed at least between the display panel and the cover layer or on an upper surface of the cover layer, wherein the light blocking pattern overlaps the pixel defining film.

In an embodiment of the present inventive concept, the display device further includes: a first light blocking pattern disposed between the display panel and the cover layer and including a first light blocking opening overlapping the pixel opening; and a second light blocking pattern disposed on the cover layer and including a second light blocking opening overlapping the pixel opening, wherein an area of the second light blocking opening is larger than an area of the first light blocking opening.

In an embodiment of the present inventive concept, the refractive index of the cover layer is about 1.53 or less; and the refractive index of the pattern layer is about 1.6 or more.

In an embodiment of the present inventive concept, each of the cover layer and the pattern layer includes a polymer material, and the cover layer further includes at least one of a pigment or a dye dispersed in the polymer material.

In an embodiment of the present inventive concept, the display panel further includes a first capping layer, a second capping layer, and an encapsulation layer, wherein the first capping layer is disposed on the second electrode, wherein the second capping layer is disposed on the first capping layer, and wherein the encapsulation layer is disposed on the second capping layer, wherein each of the first capping layer and the second capping layer includes an inorganic material, and wherein the second capping layer includes at least one of ytterbium, bismuth, or an alloy.

According to an embodiment of the present inventive concept, a display device includes: a display panel including a pixel defining film and a light-emitting element, wherein the pixel defining film includes a pixel opening, and wherein the light-emitting element includes a first electrode, a light-emitting layer, and a second electrode, wherein the first electrode is at least partially exposed through the pixel opening; a light control layer including a pattern layer and a cover layer, wherein the pattern layer overlaps the pixel opening, and wherein the cover layer covers the pattern layer and has a refractive index lower than that of the pattern layer; a window disposed on the light control layer; and a window adhesive layer disposed between the light control layer and the window to couple the light control layer and the window to each other, wherein the difference in refractive indices between the cover layer and the window is about 0.1 or less.

In an embodiment of the present inventive concept, the refractive index of the cover layer is about 1.53 or less; and the refractive index of the pattern layer is about 1.6 or more.

According to an embodiment of the present inventive concept, a method for manufacturing a display device includes: forming a pre-patterned layer on a display panel including a pixel defining film and light emitting element, wherein the pixel defining film includes a pixel opening, wherein the light-emitting element includes a first electrode, a light-emitting layer, and a second electrode, wherein the first electrode is at least partially exposed through the pixel opening, wherein the pre-patterned layer overlaps the pixel opening; performing any one of a plasma process or an extreme ultraviolet process on the pre-patterned layer to form a pattern layer from the pre-patterned layer; and forming a cover layer covering the pattern layer and having a refractive index lower than the pattern layer.

In an embodiment of the present inventive concept, the method further includes forming a light blocking pattern, which overlaps the pixel defining film, on the display panel.

In an embodiment of the present inventive concept, in the forming of the pre-patterned layer, the pre-patterned layer includes an upper surface, a lower surface opposite to the upper surface and more adjacent to the display panel than the upper surface, and a side surface connecting the upper surface and the lower surface to each other, and an angle between the side surface and the lower surface is formed to be an acute angle.

### BRIEF DESCRIPTION OF THE DRAWINGS

The above and other features of the present inventive concept will become more apparent by describing in detail embodiments thereof with reference to the accompanying drawings, in which:

FIG. 1 is a perspective view of a display device according to an embodiment of the present inventive concept;

FIG. 2 is an exploded perspective view of the display device according to an embodiment of the present inventive concept;

FIG. 3 is a cross-sectional view of the display device according to an embodiment of the present inventive concept;

FIG. 4A is a plan view of a display panel according to an embodiment of the present inventive concept;

FIG. 4B is a cross-sectional view of the display panel according to an embodiment of the present inventive concept;

FIG. 5A is an enlarged plan view of an active region of the display panel according to an embodiment of the present inventive concept;

FIG. 5B is a cross-sectional view of the display device according to an embodiment of the present inventive concept, which is taken along line I-I′ illustrated in FIG. 5A;

FIG. 5C is an enlarged plan view of one light-emitting region disposed in the active region of the display panel according to an embodiment of present the inventive concept;

FIG. 5D is an enlarged plan view of light emitting regions disposed in the active region of the display panel according to an embodiment of the present inventive concept;

FIG. 6 is a partial cross-sectional view of the display device according to an embodiment of the present inventive concept;

FIG. 7 is a partial cross-sectional view of a display device according to an embodiment of the present inventive concept;

FIG. 8 is a partial cross-sectional view of a display device according to an embodiment of the present inventive concept;

FIG. 9A is a partial cross-sectional view of a display device according to an embodiment of the present inventive concept;

FIG. 9B is a partial cross-sectional view of a display device according to an embodiment of the present inventive concept;

FIG. 10 is a partial cross-sectional view of a display device according to an embodiment of the present inventive concept; and

FIGS. 11A, 11B, 11C, 11D, 11E, 11F and 11G are cross-sectional views illustrating a method of manufacturing a display device according to an embodiment of the present inventive concept.

### DETAILED DESCRIPTION OF THE EMBODIMENTS

In this specification, it will be understood that when an element (or region, layer, portion, etc.) is referred to as being “on”, “connected to” or “coupled to” another element, the element can be directly on, connected or coupled to the other element, or intervening elements may be present.

Like reference numerals may refer to like elements throughout the specification. In addition, in the drawings, the thicknesses, ratios, and dimensions of elements may be exaggerated for clarity. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present inventive concept. Similarly, the second element may also be referred to as the first element. The terms of a singular form include plural forms unless otherwise specified. As used herein, the singular forms, “a”. “an” and “the” are intended to include the plural forms as well, unless the context clearly indicates otherwise.

In addition, terms, such as “below”, “lower”, “above”, “upper” and the like, may be used herein to describe one element's relation to another element(s) as illustrated in the figures. It will be understood that the spatially relative terms are intended to encompass different orientations of the device in use or operation in addition to the orientation depicted in the figures. For example, if the device in the figures is turned over, components described as “below” or “beneath” other components or features would then be oriented “above” the other components or features. The above terms are relative concepts and may be described based on the directions indicated in the drawings.

Hereinafter, embodiments of the present inventive concept will be described with reference to the accompanying drawings.

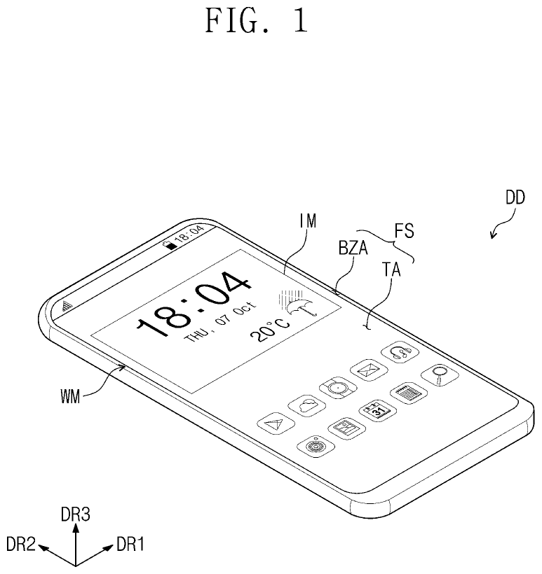

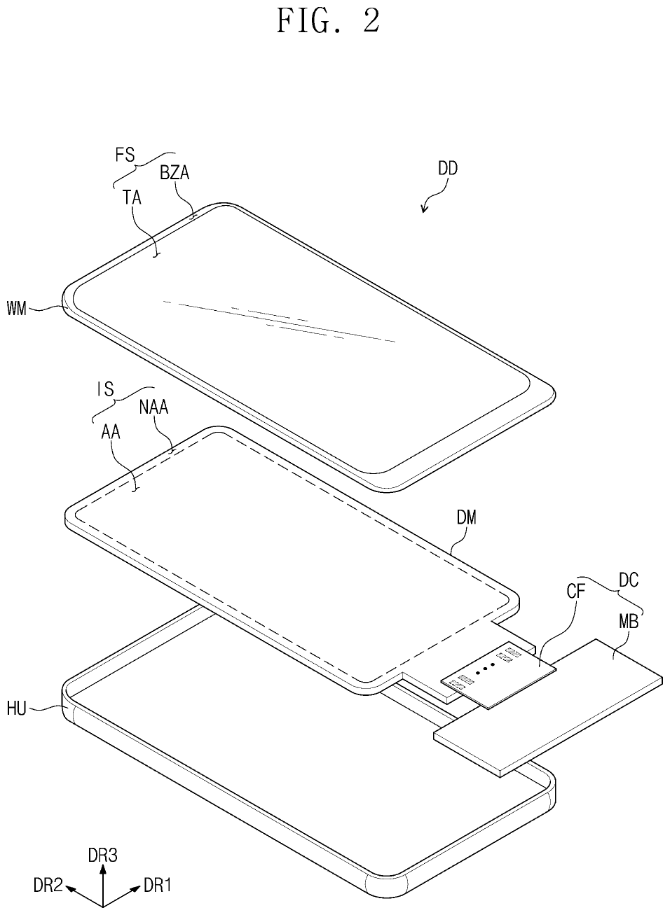

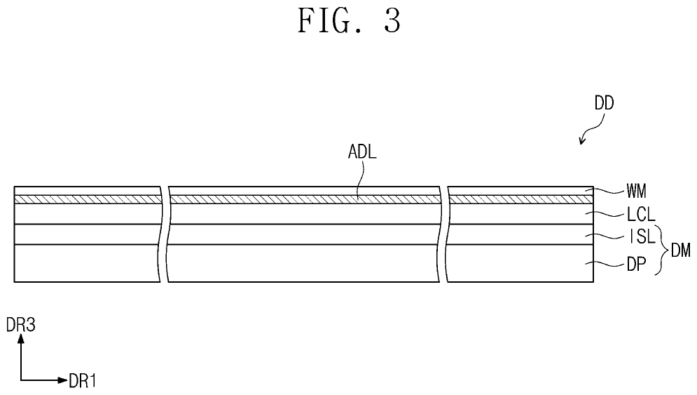

FIG. 1 is a perspective view of a display device according to an embodiment of the present inventive concept. FIG. 2 is an exploded perspective view of the display device according to an embodiment of the present inventive concept. FIG. 3 is a cross-sectional view of the display device according to an embodiment of the present inventive concept.

Referring to FIG. 1, the display device DD may be activated according to an electrical signal. The display device DD may include various embodiments. For example, the display device DD may be applied to electronic devices such as a smart watch, a tablet, a laptop computer, a computer, and a smart television. In this embodiment, a smart phone is illustrated as the display device DD.

The display device DD may display an image IM toward a third direction DR3 on a display surface FS extending parallel to each of a first direction DR1 and a second direction DR2 which intersect each other. The image IM may include a still image as well as a dynamic image. FIG. 1 illustrates a watch window and icons as examples of the image IM. The display surface FS on which the image IM is displayed may correspond to the front surface of the display device DD and may correspond to the front surface of a window WM.

In this embodiment, the front surface (or, e.g., an upper surface) and the rear surface (or, e.g., a lower surface) of each member are based on a direction in which the image IM is displayed (e.g., the third direction DR3). The front surface and the rear surface thereof may face each other in the third direction DR3, and the normal direction of each of the front surface and the rear surface may be parallel to the third direction DR3. In addition, the directions indicated by the first to third directions DR1, DR2, and DR3 are relative concepts and may be converted into other directions. In this specification, the phrase “on a plane” may mean “when viewed in the third direction DR3”.

Referring to FIG. 2, the display device DD may include a window WM, a display module DM, a driving circuit DC, and a housing HU. The window WM and the housing HU may be coupled to each other to configure the exterior of the display device DD.

The window WM may include an optically transparent insulating material. For example, the window WM may include glass or plastic. The window WM may have a multi-layered structure or a single-layered structure. For example, the window WM may include a plurality of plastic films bonded to each other by an adhesive, or a glass substrate and a plastic film bonded to each other by an adhesive.

As described above, the front surface of the window WM may provide the display surface FS of the display device DD. A transmission region TA may be an optically transparent region. For example, the transmission region TA may have a visible light transmittance of about 90% or more.

A bezel region BZA may have a relatively low light transmittance compared to the transmission region TA. The bezel region BZA may define the shape of the transmission region TA. The bezel region BZA may be adjacent to the transmission region TA and may be at least partially surrounded by the transmission region TA.

The bezel region BZA may have a predetermined color. The bezel region BZA may cover a peripheral region NAA of the display module DM to overlap the peripheral region NAA from being viewed from the outside. In addition, this is illustrated as an example, and in the window WM according to an embodiment of the present inventive concept, the bezel region BZA may be omitted.

The display module DM may display an image IM (refer to FIG. 1) and detect an external input. The display module DM may include a front surface IS including an active region AA and a peripheral region NAA. The active region AA may be activated according to an electrical signal.

In this embodiment, the active region AA may be a region in which an image IM (refer to FIG. 1) is displayed and an external input is detected, too. The transmission region TA may overlap at least a portion of the active region AA. For example, the transmission region TA may overlap the entire surface of the active region AA or at least a portion thereof.

Accordingly, a user may recognize an image IM or provide an external input through the transmission region TA. However, this is illustrated as an example, and for example, in the active region AA of the display module DM according to an embodiment of the present inventive concept, a region in which an image IM (refer to FIG. 1) is displayed and a region in which an external input is detected may be separated from each other. The present inventive concept is not limited to any one embodiment.

The peripheral region NAA may be covered by the bezel region BZA. The peripheral region NAA may be adjacent to the active region AA. The peripheral region NAA may at least partially surround the active region AA. A driving circuit or a driving line configured to drive the active region AA may be disposed in the peripheral region NAA.

The driving circuit DC may include a flexible circuit board CF and a main circuit board MB. The flexible circuit board CF may be electrically connected to the display module DM. The flexible circuit board CF may connect the display module DM and the main circuit board MB to each other. However, this is illustrated as an example, and the flexible circuit board CF according to the present inventive concept might not be connected to a separate circuit board, and the flexible circuit board CF may include a rigid substrate.

The flexible circuit board CF may be connected to the pads of the display module DM that are disposed in the peripheral region NAA. The flexible circuit board CF may provide the display module DM with an electrical signal for driving the display module DM. The electrical signal may be generated from the flexible circuit board CF or the main circuit board MB.

The main circuit board MB may include various driving circuits configured to drive the display module DM or connectors configured to supply power. The main circuit board MB may be connected to the display module DM through the flexible circuit board CF.

The housing HU may be coupled to the window WM. The housing HU may be coupled to the window WM to provide a predetermined internal space. The display module DM may be accommodated in the internal space.

The housing HU may contain a material having relatively high rigidity. For example, the housing HU may include a plurality of frames and/or plates, which include glass, plastic, or metal, or are composed of a combination thereof. The housing HU may stably protect the components of the display device DD, which are accommodated in the internal space, from external impacts and forces.

FIG. 3 is a cross-sectional view of the display device according to an embodiment of the present inventive concept. In FIG. 3, the display device DD is simply illustrated to explain the stacking relationship of the functional panels and/or functional units forming the display device DD.

The display device DD according to an embodiment of the present inventive concept may include a display module DM, a light control layer LCL, and a window WM. The display module DM may include a display panel DP and an input sensor ISL. In an embodiment of the present inventive concept, the input sensor ISL may be omitted.

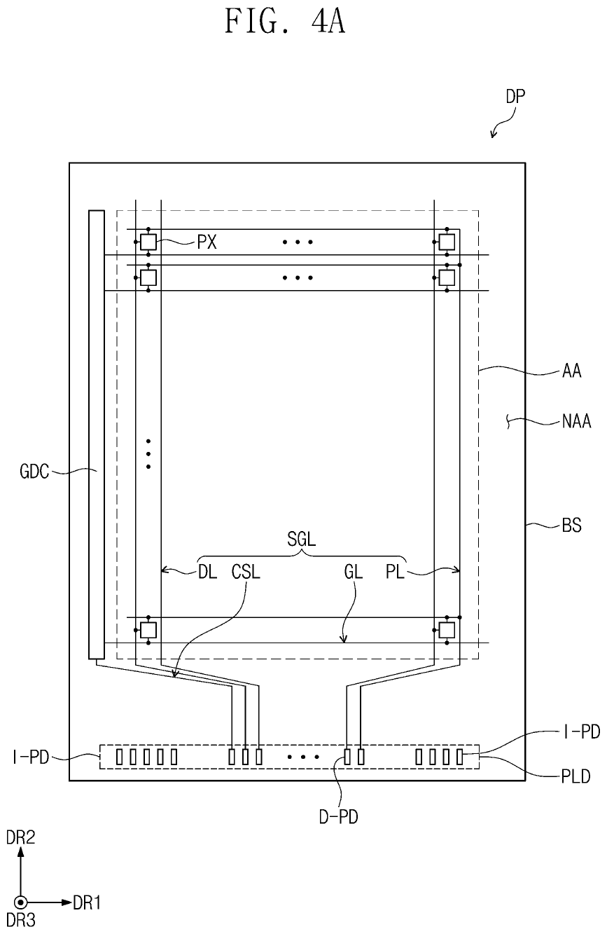

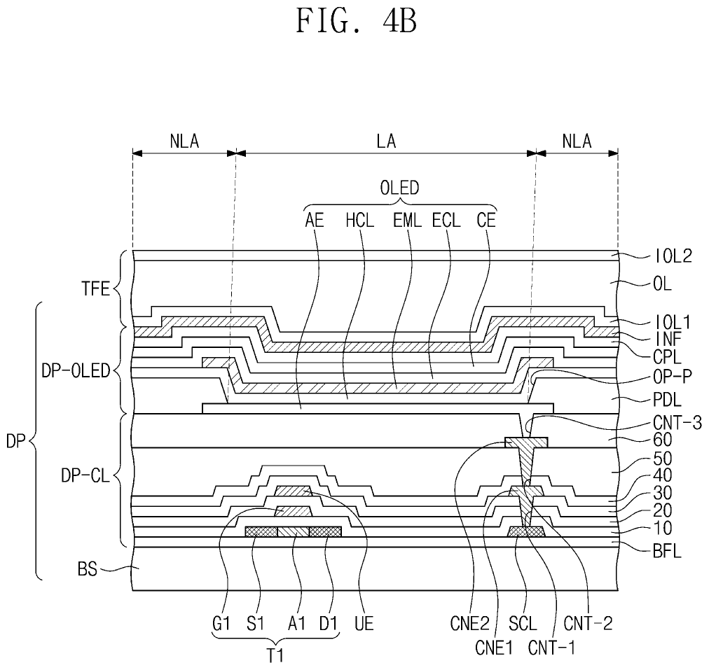

The display panel DP generates an image. The display panel DP includes a plurality of pixels PX (refer to FIG. 4A). The display panel DP according to an embodiment of the present inventive concept may be a light-emitting display panel including a light-emitting element as a display element, but the embodiment of the present inventive concept is not particularly limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include, for example, a quantum dot, a quantum rod, an inorganic LED, or the like. Hereinafter, the display panel DP will be described as an organic light-emitting display panel.

The input sensor ISL is disposed on the display panel DP. The input sensor ISL acquires the coordinate information of an external input (e.g., a touch event). The input sensor ISL may sense an external input in a capacitive manner.

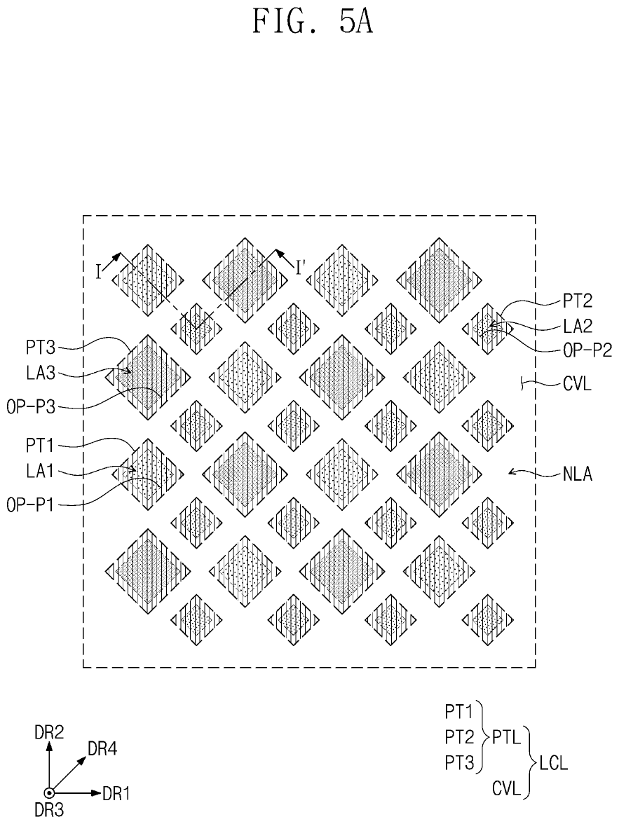

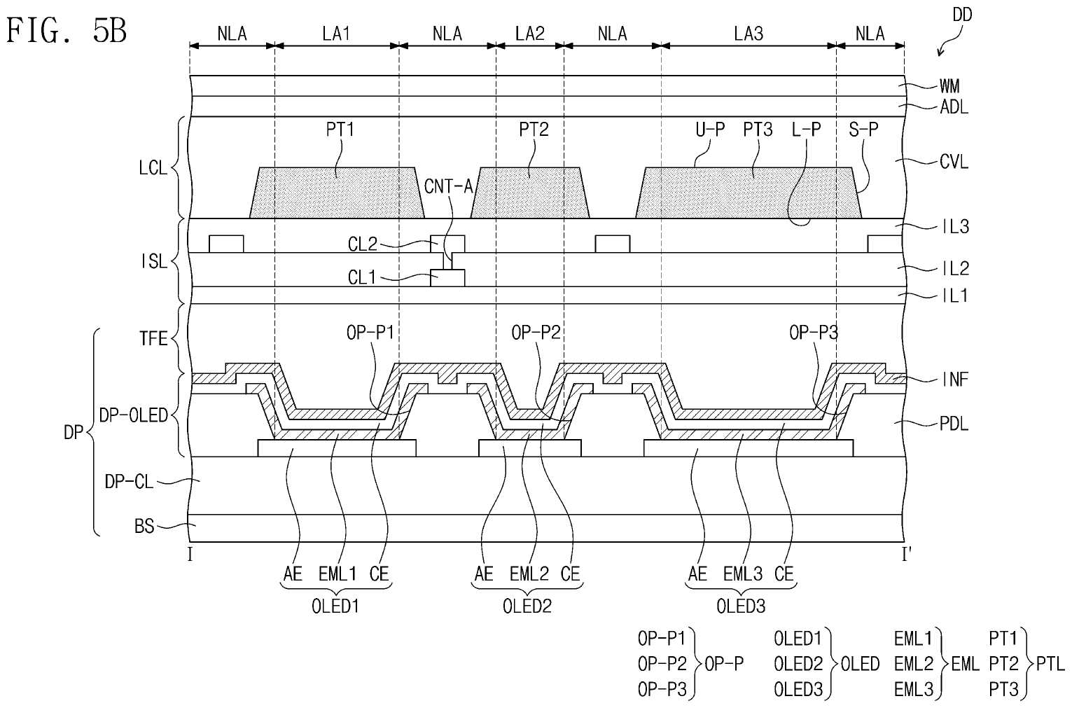

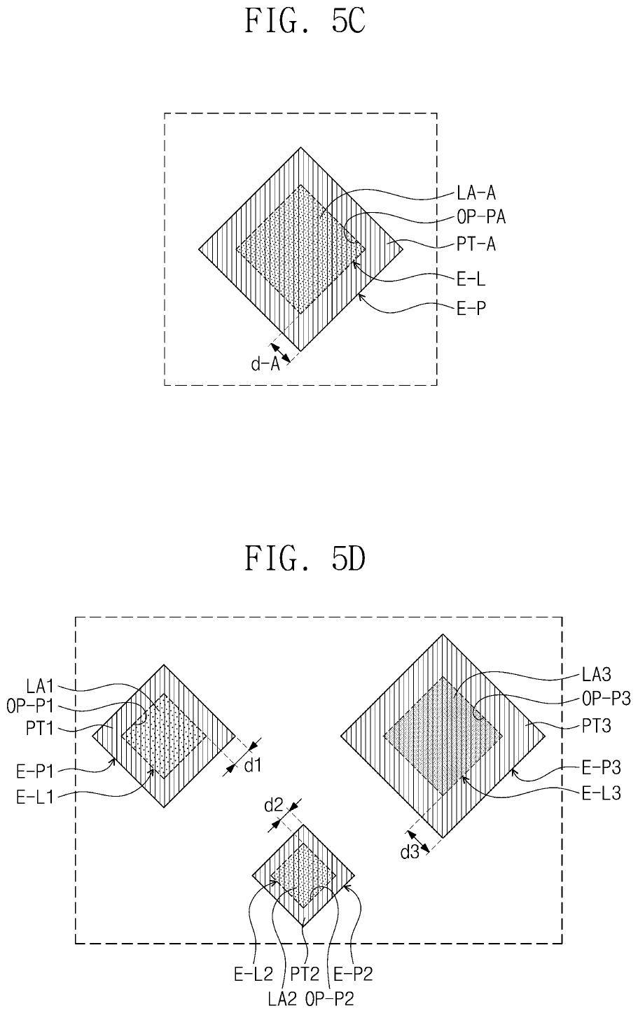

The light control layer LCL may be disposed on the input sensor ISL. The light control layer LCL according to this embodiment may include a pattern layer PT and a cover layer CVL, which will be described later with reference to FIGS. 5A and 5B. The pattern layer PTL and the cover layer CVL may have different refractive indices from each other.

The light control layer LCL may control a path of light (hereinafter, referred to as source light) generated in the display panel DP. The light control layer LCL may condense light generated in a partial region of the display panel DP. In addition, the light control layer LCL may reduce the reflectance of natural light (or, e.g., solar light) incident from above the window WM. A detailed description of this will be given later.

The light control layer LCL might not include a polarizing layer. Accordingly, light passing through the light control layer LCL and incident to the display panel DP and the input sensor ISL may be unpolarized light. The display panel DP and the input sensor ISL may receive the unpolarized light from above the light control layer LCL.

The window WM is disposed on the light control layer LCL. The window WM and the light control layer LCL may be coupled to each other by a window adhesive layer ADL. For example, the window adhesive layer ADL may be a pressure sensitive adhesive film (PSA) or an optically clear adhesive (OCA).

FIG. 4A is a plan view of a display panel according to an embodiment of the present inventive concept. FIG. 4B is a cross-sectional view of the display panel according to an embodiment of the present inventive concept.

Referring to FIG. 4A, the display panel DP may include a base layer BS divided into the active region AA and the peripheral region NAA described with reference to FIG. 2.

The display panel DP may include pixels PX and signal lines SGL. The pixels PX may be disposed in the active region AA, and the signal lines SGL may be electrically connected to the pixels PX. The display panel DP may include a driving circuit GDC and a pad portion PLD disposed in the peripheral region NAA.

The pixels PX may be arranged in the first direction DR1 and the second direction DR2. The pixels PX may include a plurality of pixel columns and a plurality of pixel rows. The plurality of pixel columns may extend in the first direction DR1 and may be arranged in the second direction DR2, and the plurality of pixel rows may extend in the second direction DR2 and may be arranged in the first direction DR1.

The signal lines SGL may include gate lines GL, data lines DL, a power line PL, and a control signal line CSL. Each of the gate lines GL may be connected to a corresponding one of the pixels PX, and each of the data lines DL may be connected to a corresponding one of the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to a pixel driving circuit.

The pad portion PLD may be a portion to which the flexible circuit board CF described with reference to FIG. 2 is connected. The pad portion PLD may include pixel pads D-PD and input pads I-PD.

The pixel pads D-PD may connect the flexible circuit board CF to the display panel DP. Each of the pixel pads D-PD may be connected to a corresponding signal line of the signal lines SGL. The pixel pads D-PD may be connected to corresponding pixels PX through a corresponding signal line of the signal lines SGL. In addition, any one of the pixel pads D-PD may be connected to the driving circuit GDC.

The input pads I-PD may connect the flexible circuit board CF to the input sensor ISL (refer to FIG. 3). Although FIG. 4A illustrates that the input pads I-PD are disposed in the display panel DP, the embodiment of the present inventive concept is not limited thereto, and the input pads I-PD may be disposed in the input sensor ISL and connected to pixel pads D-PD and to a separate circuit board.

Referring to FIG. 4B, the display panel DP may include a base layer BS, a circuit element layer DP-CL, a display element layer DP-OLED, and an encapsulation layer TFE.

The base layer BS may include a synthetic resin film. In addition, the base layer BS may include, for example, a glass substrate, a metal substrate, or an organic/inorganic composite material substrate.

At least one inorganic layer is disposed on the upper surface of the base layer BS. A buffer layer BFL increases the bonding force between the base layer BS and a semiconductor pattern. The buffer layer BFL may include, for example, a silicon oxide layer and a silicon nitride layer. The silicon oxide layer and the silicon nitride layer may be alternately stacked on each other.

The display panel DP may include a plurality of insulating layers, a semiconductor pattern, a conductive pattern, a signal line, and the like. For example, an insulating layer, a semiconductor layer, and a conductive layer are formed by coating, deposition, or the like. Thereafter, the insulating layer, the semiconductor layer, and the conductive layer may be selectively patterned through photolithography and etching processes. In this way, the semiconductor pattern, the conductive pattern, the signal line, and the like included in the circuit element layer DP-CL and the display element layer DP-OLED are formed.

The semiconductor pattern is disposed on the buffer layer BFL. The semiconductor pattern may include polysilicon. However, the embodiment of the present inventive concept is not limited thereto, and the semiconductor pattern may include amorphous silicon or metal oxide.

FIG. 4B illustrates only a portion of the semiconductor pattern, and on a plane, the semiconductor pattern may be disposed in a plurality of light-emitting regions LA1, LA2, and LA3 (refer to FIGS. 5A and 5B) to be described later. The semiconductor pattern may be arranged in a specific rule over the plurality of light-emitting regions. The semiconductor pattern has different electrical properties depending on whether it is doped or not. The semiconductor pattern may include a first region having a high doping concentration and a second region having a low doping concentration. The first region may be doped with an N-type dopant or a P-type dopant. A P-type transistor includes the first region doped with a P-type dopant.

The first region has higher conductivity than the second region and acts as an electrode or a signal line and may be connected to an electrode or a signal line. The second region substantially corresponds to an active (or, e.g., channel) of a transistor. In other words, a portion of the semiconductor pattern may be an active of a transistor, another portion thereof may be a source or drain of a transistor, and another portion thereof may be a conductive region.

As illustrated in FIG. 4B, a source SI, an active A1, and a drain D1 of a transistor T1 are formed from a semiconductor pattern. FIG. 4B illustrates a portion of a signal transmission region SCL formed from the semiconductor pattern. The signal transmission region SCL may be connected to the drain D1 of the transistor T1 on a plane.

A first insulating layer 10 to a sixth insulating layer 60 are disposed on the buffer layer BFL. The first insulating layer 10 to the sixth insulating layer 60 may be an inorganic layer or an organic layer. A gate G1 is disposed on the first insulating layer 10. An upper electrode UE may be disposed on the second insulating layer 20. A first connection electrode CNE1 may be disposed on the third insulating layer 30. The first connection electrode CNE1 may be connected to the signal transmission region SCL through a contact hole CNT-1 passing through the first to third insulating layers 10 to 30. The fourth insulating layer 40 and the fifth insulating layer 50 may be disposed above the third insulating layer 30. According to an embodiment of the present inventive concept, the fourth insulating layer 40 and the fifth insulating layer 50 may be organic layers.

A second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50.

The display element layer DP-OLED may be disposed on the circuit element layer DP-CL. According to this embodiment, the display element layer DP-OLED may include a light-emitting element OLED, a pixel defining film PDL, a first capping layer CPL, and a second capping layer IFN.

The light-emitting element OLED is disposed on the sixth insulating layer 60. According to this embodiment, the light-emitting element OLED may include a first electrode AE, a hole control layer HCL, a light-emitting layer EML, an electron control layer ECL, and a second electrode CE.

The first electrode AE is disposed on the sixth insulating layer 60. The first electrode AE is connected to the second connection electrode CNE2 through a contact hole CNT-3 passing through the sixth insulating layer 60. The pixel defining film PDL is disposed on the sixth insulating layer 60. A pixel opening OP-P is provided in the pixel defining film PDL. The pixel opening OP-P exposes at least a portion of the first electrode AE. A light-emitting region LA may correspond to a portion of the first electrode AE exposed through the pixel opening OP-P in the pixel defining film PDL. The non-light-emitting region NLA corresponds to a region excluding the light-emitting region LA within the active region AA (refer to FIG. 2). For example, the non-light-emitting region NLA may overlap the pixel defining film PDL.

In an embodiment of the inventive concept, the pixel defining film PDL may include a light absorbing material. The pixel defining film PDL may include a black coloring agent. The black coloring agent may include a black dye and a black pigment. The black coloring agent may include carbon black, a metal such as chromium, or an oxide thereof.

The hole control layer HCL is disposed on the first electrode AE. The hole control layer HCL may be commonly disposed in the light-emitting region LA and the non-light-emitting region NLA. The hole control layer HCL may include at least one of a hole transport layer and a hole injection layer.

The light-emitting layer EML is disposed on the hole control layer HCL. The light-emitting layer EML may be disposed in a region corresponding to the pixel opening OP-P. For example, the light-emitting layer EML may be disposed to correspond to the light-emitting region LA.

The electron control layer ECL is disposed on the light-emitting layer EML. The electron control layer ECL may include at least one of an electron transport layer and an electron injection layer. The second electrode CE is disposed on the electron control layer ECL. The electron control layer ECL and the second electrode CE may be commonly disposed in the light-emitting region LA and the non-light-emitting region NLA.

The first capping layer CPL is disposed on the second electrode CE. The first capping layer CPL may be commonly disposed in the light-emitting region LA and the non-light-emitting region NLA.

According to an embodiment of the present inventive concept, the first capping layer CPL may include an inorganic material. The first capping layer CPL may be formed through a sputtering deposition process.

By covering the second electrode CE, the first capping layer CPL may protect the second electrode CE and the light-emitting layer EML from external moisture penetration or contamination. In addition, by adjusting the refractive index and thickness of the first capping layer CPL, the amount of light that is reflected on the interface between the second electrode CE and the first capping layer CPL may be reduced.

The second capping layer INF is disposed on the first capping layer CPL. For example, the second capping layer INF may be disposed directly on the first capping layer CPL. The second capping layer INF may be commonly disposed in the light-emitting region LA and the non-light-emitting region NLA.

The second capping layer INF may be a layer configured to prevent external light from being reflected from the second electrode CE. For example, since destructive interference occurs between light reflected, which is from the surface of the second capping layer INF, and light, which is reflected from the second electrode CE, the amount of external light reflected from the surface of the second electrode CE may be reduced. In this case, the destructive interference may refer to a phenomenon in which light reflected from an interface offset (or, e.g., cancel) each other when the light reflected from the interface have the same reflection amplitude with a phase of about 180 degrees therebetween (e.g., the wavelengths of the light rays are out of phase with each other by about 180 degrees).

The thicknesses of the second capping layer INF and the first capping layer CPL may be adjusted so that the destructive interference occurs between the light reflected from the surface of the second capping layer INF and the light reflected from the second electrode CE.

The second capping layer INF may include an inorganic material. For example, the second capping layer INF may include at least one of bismuth (Bi) and/or ytterbium (Yb). The material which forms the second capping layer INF may be composed of, for example, bismuth (Bi) or ytterbium (Yb). In addition, the second capping layer INF may include an alloy. For example, the second capping layer INF may include a YbₓBi_{y}-mixed deposition material. The second capping layer INF may be formed through, for example, a sputtering deposition process.

The encapsulation layer TFE is disposed on the second capping layer INF. The encapsulation layer TFE may be a thin-film encapsulation layer. The encapsulation layer TFE may be a single layer or a stack of a plurality of layers. The encapsulation layer TFE includes at least one organic film.

According to an embodiment of the present inventive concept, the encapsulation layer TFE may include a first inorganic layer IOL1, an organic layer OL, and a second inorganic layer IOL2. The first inorganic layer IOL1 may be disposed on the second capping layer INF. The organic layer OL may be disposed on the first inorganic layer IOL1. The second inorganic layer IOL2 may be disposed on the organic layer OL to cover the organic layer OL.

The first inorganic layer IOL1 and the second inorganic layer IOL2 may protect the display element layer DP-OLED from moisture/oxygen, and the organic layer OL may protect the display element layer DP-OLED from foreign substances such as dust particles.

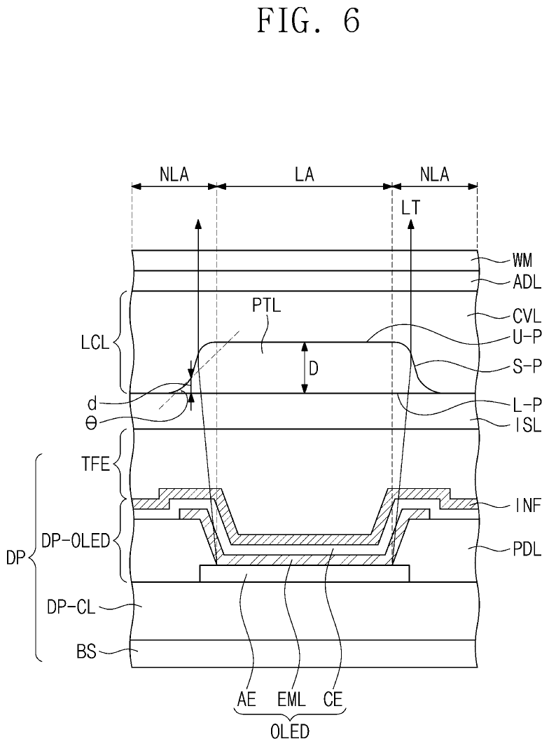

FIG. 5A is an enlarged plan view of an active region of the display panel according to an embodiment of the present inventive concept. FIG. 5B is a cross-sectional view of the display device according to an embodiment of the present inventive concept, taken along line I-I′ illustrated in FIG. 5A. FIG. 5C is an enlarged plan view of one light-emitting region disposed in the active region of the display panel according to an embodiment of the present inventive concept. FIG. 5D is an enlarged plan view of light emitting regions disposed in the active region of the display panel according to an embodiment of the present inventive concept. FIG. 6 is a partial cross-sectional view of the display device according to an embodiment of the present inventive concept.

FIG. 5A is a plan view illustrating the relationship of the light control layer LCL and the light-emitting regions LA1, LA2, and LA3 in a direction viewed from the front surface of the display device DD. FIGS. 5C and 5D are enlarged plan views illustrating a portion of FIG. 5A.

Referring to FIGS. 5A and 5B, the display device DD according to this embodiment may include a display panel DP, an input sensor ISL, a light control layer LCL, a window adhesive layer ADL, and a window WM, and the display panel DP may include a base layer BS, a circuit element layer DP-CL, a display element layer DP-OLED, and an encapsulation layer TFE.

In FIG. 5B, the base layer BS, the circuit element layer DP-CL, and the encapsulation layer TFE are illustrated as a single layer, and among the components described in FIG. 48, the pixel defining film PDL, the first electrode AE, the light-emitting layer EML, and the second electrode CE of the light-emitting element OLED, and the second capping layer INF are illustrated in the display element layer DP-OLED. Same/similar reference numerals may be used for the same/similar components as those described with reference to FIGS. 1 to 4B, and duplicate descriptions may be omitted.

According to this embodiment, the pixel defining film PDL may include a plurality of pixel openings OP-P. The pixel openings OP-P may include a first pixel opening OP-P1, a second pixel opening OP-P2, and a third pixel opening OP-P3 having different areas on a plane. According to an embodiment of the present inventive concept, on a plane, the area of the first pixel opening OP-Pt may be larger than the area of the second pixel opening OP-P2 and smaller than the area of the third pixel opening OP-P3.

According to this embodiment of the present inventive concept, there may be a plurality of light-emitting elements OLED, and the light-emitting elements OLED may include a first light-emitting element OLED1, a second light-emitting element OLED2, and a third light-emitting element OLED3.

The first light-emitting element OLED1 may include a first electrode AE, which is exposed by the first pixel opening OP-P1, a first light-emitting layer EML1, which is configured to provide a first color light, and a second electrode CE. The first electrode AE included in the first light-emitting element OLED1 may be exposed by the first pixel opening OP-P1 to define the first light-emitting region LA1.

The second light-emitting element OLED2 may include a first electrode AE, which is exposed by the second pixel opening OP-P2, a second light-emitting layer EML2, which is configured to provide a second color light, and a second electrode CE. The first electrode AE included in the second light-emitting element OLED2 may be exposed by the second pixel opening OP-P2 to define the second light-emitting region LA2.

The third light-emitting element OLED3 may include a first electrode AE, which is exposed by the third pixel opening OP-P3, a third light-emitting layer EML3, which is configured to provide a third color light, and a second electrode CE. The first electrode AE included in the third light-emitting element OLED3 may be exposed by the third pixel opening OP-P3 to define the third light-emitting region LA3.

Each of the first to third light-emitting elements OLED1, OLED2, and OLED3 illustrated in FIG. 5B may correspond to the light-emitting element OLED illustrated in FIG. 4B. In addition, each of the first to third light-emitting regions LA1, LA2, and LA3 illustrated in FIGS. 5A and 5B may correspond to the light-emitting region LA illustrated in FIG. 4B.

As illustrated in FIG. 5A, the first and third light-emitting regions LA1 and LA3 may be arranged to cross each other along the first direction DR1 on a plane. For example, the first and third light-emitting regions LA1 and LA3 may be alternately arranged along the first direction DR1. The second light-emitting regions LA2 may be disposed in a pixel column different from those of the first and third light-emitting regions LA1 and LA3 along the second direction DR2, and each of the second light-emitting regions LA2 may be arranged in the same pixel row along the first direction DR1. The first and second light-emitting regions LA1 and LA2 may be arranged to cross each other along a fourth direction DR4, which may be a diagonal direction with respect to the first and second directions DR1 and DR2. For example, the first and second light-emitting regions LA1 and LA2 may be alternately arranged along the fourth direction DR4. The second and third light-emitting regions LA2 and LA3 may be arranged to cross each other along the fourth direction DR4. For example, the second and third light-emitting regions LA2 and LA3 may be alternately arranged along the fourth direction DR4. However, the arrangement of the first to third light-emitting regions LA1, LA2, and LA3 is not limited thereto.

The first to third color lights may have different colors from each other. For example, the first color light provided from the first light-emitting region LA1 may be red light, the second color light provided from the second light-emitting region LA2 may be green light, and the third color light provided from the third light-emitting region LA3 may be blue light.

However, the embodiment of the present inventive concept is not limited thereto, and the first to third color lights may be selected as a combination of the three color lights which are mixed to generate white light. In addition, the first to third color lights may have the same color.

As illustrated in FIG. 5B, the input sensor ISL may be disposed directly on the encapsulation layer TFE.

According to this embodiment of the present inventive concept, the input sensor ISL may include a first insulating layer IL1, a first conductive layer CL1, a second insulating layer IL2, a second conductive layer CL2, and a third insulating layer IL3. The first insulating layer IL1 may be disposed on the encapsulation layer TFE. The first conductive layer CL1 may be disposed on the first insulating layer IL1. The second insulating layer IL2 may be disposed on the first insulating layer IL1 and may cover the first conductive layer CL1. The second conductive layer CL2 may be disposed on the second insulating layer IL2. The second conductive layer CL2 may be electrically connected to the first conductive layer CL1 through a contact hole CNT-A formed through the second insulating layer IL2. The third insulating layer IL3 may be disposed on the second insulating layer IL2 and may cover the second conductive layer CL2.

Each of the first insulating layer IL1, the second insulating layer IL2, and the third insulating layer IL3 may include at least one of an inorganic material or an organic material. Each of the first conductive layer CL1 and the second conductive layer CL2 may have conductivity and be provided as a single layer or a plurality of layers.

At least one of the first conductive layer CL1 or the second conductive layer CL2 may be provided as mesh lines to form a mesh structure on a plane. The mesh lines may be spaced apart from the light-emitting layer EML on a plane. Accordingly, although the input sensor ISL is formed on the display panel DP, light formed from the light-emitting element OLED may be provided to a user without interference of the input sensor ISL.

In this embodiment, the light control layer LCL may be disposed on the input sensor ISL.

The light control layer LCL may include a pattern layer PTL and a cover layer CVL.

The pattern layer PTL may be disposed on the third insulating layer IL3. The pattern layer PTL may be composed of a plurality of patterns PT1, PT2, and PT3.

According to an embodiment of the present inventive concept, the pattern layer PTL may include a first pattern PT1, a second pattern PT2, and a third pattern PT3. The first pattern PT1 may overlap the first pixel opening OP-P1. The second pattern PT2 may overlap the second pixel opening OP-P2, and the third pattern PT3 may overlap the third pixel opening OP-P3.

The first pattern PT1 may overlap the first light-emitting region LA1. For example, the first pattern PT1 may overlap the entire region of the first light-emitting region LA1. The second pattern PT2 may overlap the second light-emitting region LA2. For example, the second pattern PT2 may overlap the entire region of the second light-emitting region LA2. The third pattern PT3 may overlap the third light-emitting region LA3. For example, the third pattern PT3 may overlap the entire region of the third light-emitting region LA3.

As illustrated in FIG. 5A, the first to third patterns PT1, PT2, and PT3 may have an arrangement corresponding to the arrangement of the first to third light emitting regions LA1, LA2 and LA3. For example, on a plane, the first and third patterns PT1 and PT3 may be alternately arranged along the first direction DR1. Each of the second patterns PT2 may be arranged along the first direction DR1. The first and second patterns PT1 and PT2 may be alternately arranged along the fourth direction DR4. The second and third patterns PT2 and PT3 may be alternately arranged along the fourth direction DR4.

However, the arrangement of the first to third patterns PT1, PT2, and PT3 is not limited thereto and may vary according to the arrangement of the first to third light-emitting regions LA1, LA2, and LA3.

FIG. 5C is an enlarged view illustrating: any one pattern PT-A (hereinafter, one pattern) among the first to third patterns PT1, PT2, and PT3 illustrated in FIG. 5A; and a light-emitting region LA-A corresponding to the one pattern PT-A among the first to third light-emitting regions LA1, LA2 and LA3 illustrated in FIG. 5A. Hereinafter, the description of the one pattern PT-A to be described with reference to FIG. 5C may be applied to all of the first to third patterns PT1, PT2, and PT3.

On a plane, the area of the one pattern PT-A may be larger than the area of the corresponding light-emitting region LA-A. Accordingly, on a plane, an edge E-P of the one pattern PT-A may surround an edge E-L of the corresponding light-emitting region LA-A. In this case, the edge E-P of the one pattern PT-A may be spaced apart from the edge E-L of the corresponding light-emitting region LA-A by a predetermined distance d-A (hereinafter referred to as “separation distance”).

In this specification, the edge E-P of the one pattern PT-A may be the outermost portion of the one pattern PT-A, which is in contact with the third insulating layer IL3 (refer to FIG. 5B) of the input sensor ISL (refer to FIG. 5B). In this specification, the edge E-L of the light-emitting region LA-A may correspond with the outermost portion of the first electrode AE (refer to FIG. 5B), which is exposed from the pixel defining film PDL through a pixel opening OP-PA of the pixel defining film PDL (refer to FIG. 5B).

According to this embodiment, the separation distance d-A between the edge E-P of the one pattern PT-A and the edge E-L of the light-emitting region LA-A may be about 0.5 micrometers or more.

For example, on a plane, the one pattern PT-A covers the entire region of the corresponding light-emitting region LA-A and has a larger area than the corresponding light-emitting region LA-A, so that light emitted in the lateral direction from the light-emitting element OLED (refer to FIG. 5B) may pass through the cover layer CVL. Through this, the one pattern PT-A may condense the light emitted in the lateral direction. A detailed description of this will be given later.

FIG. 5D is an enlarged view of each of the first to third patterns PT1, PT2, and PT3 illustrated in FIG. 5A.

On a plane, the separation distance between an edge E-P1 of the first pattern PT1 and an edge E-L1 of the first light-emitting region LA1 is defined as a first distance d1. On a plane, the separation distance between an edge E-P2 of the second pattern PT2 and an edge E-L2 of the second light-emitting region LA2 is defined as a second distance d2. On a plane, the separation distance between an edge E-P3 of the third pattern PT3 and an edge E-L3 of the third light-emitting region LA3 is defined as a third distance d3.

According to an embodiment of the present inventive concept, taking the characteristics of light emitted from the first to third light-emitting regions LA1, LA2, and LA3 into consideration, the values of the first distance d1, the second distance d2, and the third distance d3 may be set differently from each other.

Referring to FIG. 5B again, each of the first to third patterns PT1, PT2, and PT3 according to an embodiment of the present inventive concept may have a trapezoidal shape from a cross sectional view. Each of the first to third patterns PT1, PT2, and PT3 may include an upper surface U-P, a lower surface L-P facing the upper surface U-P and closer to the display panel DP than the upper surface U-P, and a side surface S-P connecting the upper surface U-P and the lower surface L-P to each other. In this case, the lower surface L-P may come in contact with the third insulating layer IL3.

According to an embodiment of the present inventive concept, the pattern layer PTL may include a polymer material. The pattern layer PTL may include a high refractive monomer. For example, the pattern layer PTL may contain an acrylic resin. The pattern layer PTL may further include nanoparticles.

The cover layer CVL may be disposed on the second insulating layer IL2. The cover layer CVL may come in contact with the upper surface U-P and the side surface S-P of the pattern layer PTL and cover the pattern layer PTL.

According to an embodiment of the present inventive concept, the cover layer CVL may be a layer in which a dye and/or a pigment are dispersed in a polymer resin. The dye and the pigment included in the cover layer CVL may be materials that transmit only light in a specific wavelength range among the light emitted from the light-emitting elements OLED1, OLED2, and OLED3.

In an embodiment of the present inventive concept, the dye and pigment may be a layer that absorbs light in a wavelength range of about 490 nm to about 505 nm and light in a wavelength range of about 585 nm to about 600 nm and transmits the remaining light. As the dye and the pigment included in the cover layer CVL absorb light in a specific wavelength range and transmit light in the remaining wavelength range, the dye and the pigment may prevent the reflection of external light and adjust the color of the light emitted from the display panel DP.

According to an embodiment of the present inventive concept, the cover layer CVL may further include an adhesive material. Accordingly, the window adhesive layer ADL, which is disposed on the cover layer CVL to couple the window WM and the cover layer CVL to each other, may be omitted.

According to an embodiment of the present inventive concept, the cover layer CVL may be provided by being patterned through a photolithography process or an inkjet printing process.

According to an embodiment of the present inventive concept, the refractive index of the pattern layer PTL may be greater than that of the cover layer CVL.

FIG. 6 is an enlarged cross-sectional view of any one of the first to third patterns PT1, PT2, and PT3 illustrated in FIG. 5B. Hereinafter, referring to FIG. 6, a change in the path of light due to the difference in refractive indices between the pattern layer PTL and the cover layer CVL will be described.

The refractive index of the pattern layer PTL may be about 1.6 or more. The refractive index of the cover layer CVL may be about 1.53 or less. The term “refractive index” in this specification refers to the refractive index of green light.

Since the light control layer LCL includes the pattern layer PTL, which has a high refractive index, and the cover layer CVL, which has a low refractive index, the light generated by the light-emitting element OLED may be condensed to increase the luminous efficiency of the display panel DP.

For example, light LT traveling in the lateral direction among the light generated by the light-emitting element OLED may be refracted on the side surface SP of the pattern layer PTL, and accordingly, the path of the light LT traveling in the lateral direction may be changed so that the light LT travels in the front direction. Therefore, since the light emission efficiency of each of the light emitting elements OLED1, OLED2, and OLED3 (refer to FIG. 5B) in the front direction is increased, the light efficiency of the display panel DP may be increased. As the resolution of the display panel DP increases, the light efficiency of the display panel DP may be more effectively increased.

The light efficiency of the display device DD including the light control layer LCL of the present inventive concept may be increased by about 10% or more, when compared to the light efficiency of a display device which does not include a separate layer configured to control the light path. In this case, the greater the difference in refractive indices between the pattern layer PTL and the cover layer CVL, the more refracted the light LT traveling in the lateral direction may be on the side surface S-P of the pattern layer PTL. Accordingly, the ratio of light which travels in the front direction increases, so that the degree of in light efficiency may also be increased.

According to an embodiment of the present inventive concept, the thickness D of the pattern layer PTL may be about 1.5 micrometers to about 3.5 micrometers. In this case, the thickness D of the pattern layer PTL is the maximum thickness between the upper surface U-P and the lower surface L-P of the pattern layer PTL. When the thickness D of the pattern layer PTL is less than about 1.5 micrometers and when the thickness D of the pattern layer PTL is more than about 3.5 micrometers, it may be difficult to perform a process, and process precision may be reduced, and thus, reducing process yield.

According to an embodiment of the present inventive concept, the angle between the lower surface L-P and the side surface S-P of the pattern layer PTL may be an acute angle. As illustrated in FIG. 6, the side surface S-P of the pattern layer PTL according to an embodiment of the present inventive concept may be formed to have an irregular inclination with respect to the lower surface L-P of the pattern layer PTL. In this case, at a point at which a thickness d from the lower surface L-P to the side surface S-P of the pattern layer PTL is about ⅓ of the maximum thickness D of the pattern layer PTL, the angle formed by the lower surface L-P with respect to the tangential direction of the side surface S-P may be defined as a taper angle θ.

TABLE 1

Refractive index

| | 1.55 | 1.53 | 1.56 | Light efficiency |
|---|---|---|---|---|
| Taper angle (θ) | R | G | B | Average |
| 55 | 217% | 256% | 205% | 226% |
| 60 | 130% | 149% | 129% | 136% |
| 63 | 108% | 122% | 109% | 113% |
| 65 | 97% | 110% | 99% | 102% |
| 68 | 86% | 96% | 89% | 90% |
| 70 | 80% | 89% | 84% | 84% |

Table 1 describes the light efficiencies for each of red light, green light, and blue light according to the taper angles θ of the pattern layer PTL.

The refractive index of the cover layer CVL (e.g., the refractive index with respect to the green light) may be about 1.53. In this case, the refractive index of the cover layer CVL with respect to the red light may be about 1.55, and the refractive index of the cover layer CVL with respect to the blue light may be about 1.56. In addition, the refractive index of the pattern layer PTL may be about 1.6 or more, and the thickness D of the pattern layer PTL may be about 2.5 micrometers to about 3.5 micrometers.

Table 1 shows the light efficiencies which are calculated respectively based on when the taper angles θ are about 55 degrees, about 60 degrees, about 63 degrees, about 65 degrees, about 68 degrees, and about 70 degrees.

Referring to Table 1, when the taper angle θ is about 65 degrees or less, light efficiency may increase. In addition, as the taper angle θ decreases, light efficiency may increase. Therefore, according to this embodiment, the taper angle θ of the pattern layer PTL may be about 65 degrees or less.

Desirably, the taper angle θ of the pattern layer PTL may be about 40 degrees to about 65 degrees. When the taper angle θ is less than about 40 degrees, high efficiency may be maintained, but although the taper angle θ becomes smaller than about 40 degrees, light efficiency does not further increase, and the precision of the process is reduced, and thus a process error may occur. When the taper angle θ is greater than about 65 degrees, the degree of refraction of the light passing through the pattern layer PTL, that is, the degree of light condensing is low, and thus, light efficiency might not be sufficient.

According to this embodiment, since the display element layer DP-OLED includes the second capping layer INF, the reflection of external light may be reduced due to destructive interference with respect to reflected light, but at the same time, the amount of light, which is emitted from the light-emitting element OLED, is reduced, thus somewhat reducing light efficiency. However, according to the present inventive concept, by condensing light in the front direction in the light control layer LCL, the reflection of external light at the second electrode CE2 may be reduced and light efficiency may be increased as well.

In this embodiment, the window adhesive layer ADL may be disposed on the cover layer CVL. The window adhesive layer ADL may have a refractive index of about 1.45 to about 1.5.

According to this embodiment, the difference between the refractive index of the window adhesive layer ADL and the refractive index of the cover layer CVL may be about 0.1 or less. By reducing the difference between the refractive index of the window adhesive layer ADL and the refractive index of the cover layer CVL, interlayer interface reflection may reduce the generated amount of light when external light passing through the window WM is transmitted to the light control layer L-CL through the window adhesive layer ADL,

Accordingly, as the light control layer LCL according to the present inventive concept reduces the reflection of external light by minimizing the difference in refractive indices between the window adhesive layer ADL and the cover layer CVL, the display device DD (refer to FIG. 1) with increased visibility may be provided.

According to an embodiment of the present inventive concept, the pattern layer PTL and the cover layer CVL of the light control layer LCL may reduce the reflection of external light without attaching a polarizing film or adding a color filter layer. Accordingly, this may contribute to a reduction in the thickness of the display device DD and be applied to a foldable display device. In addition, while the color filter layer requires patterning of each of the color filter layers for red light, green light, and blue light, the first to third patterns PT1, PT2, and PT3 of the present inventive concept may be patterned with one mask. Accordingly, the display device DD with a simplified process may be provided.

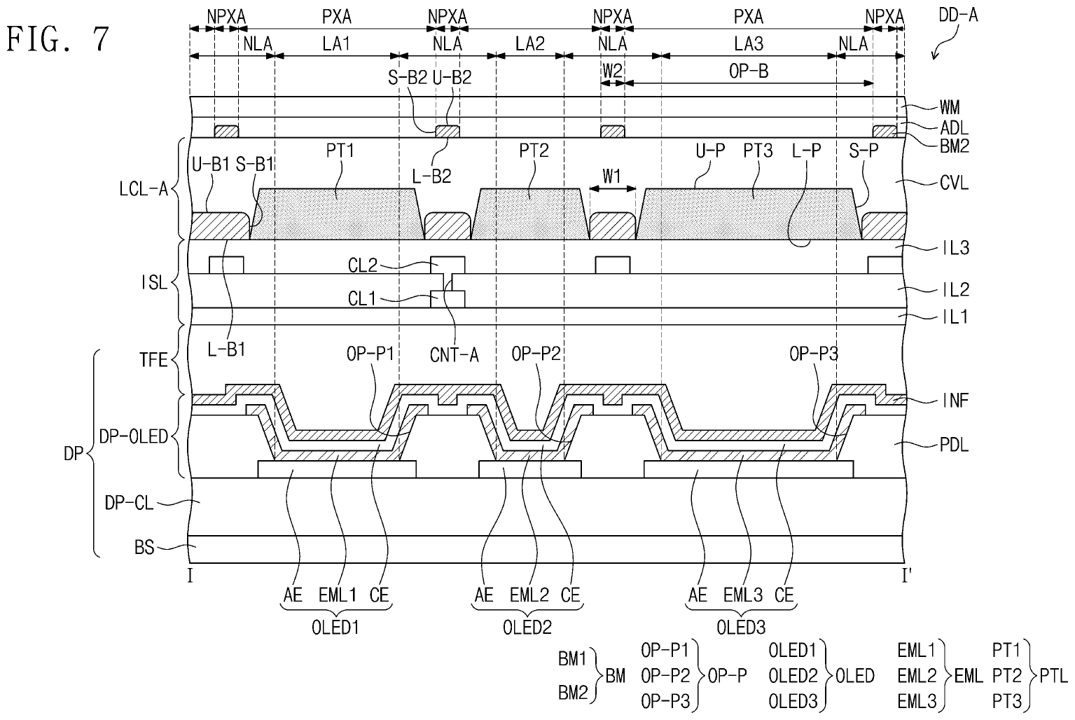

FIG. 7 is a partial cross-sectional view of a display device according to an embodiment of the present inventive concept.

According to this embodiment, the display device DD-A may include a display panel DP, an input sensor ISL, and a light control layer LCL-A. The light control layer LCL-A may include a pattern layer PTL, a cover layer CVL, and a light blocking pattern BM. Same/similar reference numerals will be used for the same/similar components as those described with reference to FIGS. 1 to 6, and duplicate descriptions may be omitted.

The light control layer LCL-A according to this embodiment may further include a light blocking pattern BM. According to an embodiment of the present inventive concept, the light blocking pattern BM may include a first light blocking pattern BM1 and a second light blocking pattern BM2. The first blocking pattern BM1 and the second blocking pattern BM2 may be disposed in different layers from each other.

The first blocking pattern BM1 may be disposed on the third insulating layer IL3 of the input sensor ISL. The first blocking pattern BM1 may be disposed between adjacent patterns among the first to third patterns PT1, PT2, and PT3. For example, on a plane, the first blocking pattern BM1 may be disposed to at least partially surround the pattern layer PTL.

The first blocking pattern BM1 may overlap the non-light-emitting region NLA and might not overlap the light-emitting regions LA1, LA2, and LA3. For example, the first blocking pattern BM1 may overlap the pixel defining film PDL.

The first light blocking pattern BM1 may include a lower surface L-B1, an upper surface U-B1, and a side surface S-B1. The lower surface L-B1 is in contact with the third insulating layer IL3. The upper surface U-B1 is opposite to the lower surface L-B1, and the side surface S-B1 connects the lower surface L-B1 and the upper surface U-B1 to each other.

According to an embodiment of the present inventive concept, as illustrated in FIG. 7, the side surface S-B1 of the first blocking pattern BM1 may be spaced apart from the side surface S-P of the pattern layer PTL. In this case, the cover layer CVL may be disposed on the top surface U-B1 and the side surface S-B1 of the first light blocking pattern BM1 as well as the top surface UP and the side surface SP of the pattern layer PTL, and may cover the pattern layer PTL and the first light blocking pattern BM1. For example, the cover layer CVL may come in contact with the top surface U-B1 and the side surface S-B1 of the first light blocking pattern BM1 as well as the top surface UP and the side surface SP of the pattern layer PTL.

According to an embodiment of the present inventive concept, the side surface S-B1 of the first blocking pattern BM1 may come in contact with the side surface S-P of an adjacent pattern layer PTL. For example, the first blocking pattern BM1 may be disposed to cover a portion of the side surface S-P of the pattern layer PTL. In this case, the cover layer CVL may come in contact with the upper surface U-B1 of the first light blocking pattern BM1 and cover the first light blocking pattern BM1.

The second light blocking pattern BM2 may be disposed on the cover layer CVL. The second blocking pattern BM2 may overlap the non-light-emitting region NLA and might not overlap the light-emitting regions LA1, LA2, and LA3. For example, the second light blocking pattern BM2 may overlap the pixel defining film PDL and not the pixel opening OP.

The second light blocking pattern BM2 may include a lower surface L-B2, an upper surface U-B2, and a side surface S-B2. The lower surface L-B2 may be disposed on the cover layer CVL. For example, the lower surface L-B2 may be in contact with the cover layer CVL. The upper surface U-B2 may be opposite to the upper surface U-B2, and the side surface S-B2 may connect the lower surface L-B2 and the upper surface U-B2 to each other. According to this embodiment, the second blocking pattern BM2 may include a light blocking opening OP-B defined by the side surface S-B2 of the second blocking pattern BM2.

The area of the light blocking opening OP-B may be a pixel region PXA. The pixel region PXA may be a region in which light generated by the light-emitting element OLED is emitted to the outside. A non-pixel region NPXA may be a region, adjacent to and excluding the pixel region PXA, and the non-pixel region NPXA may at least partially surround the pixel region PXA.

Each of the first blocking pattern BM1 and the second blocking pattern BM2 may include a light absorbing material. Each of the first blocking pattern BM1 and the second blocking pattern BM2 may be a pattern having a black color and include a black coloring agent. The black coloring agent may include a black dye and a black pigment. The black coloring agent may include carbon black, a metal such as chromium, or an oxide thereof.

According to this embodiment, each of the first blocking pattern BM1 and the second blocking pattern BM2 overlaps the first conductive layer CL1 and the second conductive layer CL2 of the input sensor ISL, so that the reflection of external light by the first conductive layer CL1 and the second conductive layer CL2 may be reduced.

In addition, as the second light blocking pattern BM2 reduces the interface on which external light is reflected and at which the window adhesive layer ADL and the cover layer CVL come in contact with each other, the reflection of external light on the interface between the window adhesive layer ADL and the cover layer CVL may be reduced. Accordingly, due to the light control layer LCL-A according to this embodiment, the display device DD-A with increased visibility may be provided.

By controlling the width of the light blocking opening OP-B of the second light blocking pattern BM2, the characteristic of light may be adjusted. For example, by increasing the width of the light blocking opening OP-B, light efficiency may be increased. By reducing the width of the light blocking opening OP-B, a viewing angle may be reduced, and this may be applied to a private mode of the display device DD-A.

The width on the cross section of the first blocking pattern BM1 may be defined as a first width W1, and the width on the cross section of the second blocking pattern BM2 may be defined as a second width W2.

According to an embodiment of the present inventive concept, the second width W2 may be smaller than the first width W1. By setting the width of the light blocking opening OP-B of the second blocking pattern BM2 to be relatively large, light emitted from the side while passing through the light control layer LCL-A may be prevented from being absorbed by the second blocking pattern BM2. Accordingly, the display device DD having increased light efficiency may be provided. However, present inventive concept is not limited thereto. According to an embodiment of the present inventive concept, the first width W1 and the second width W2 may be equal to each other.

Any one of the first blocking pattern BM1 and the second blocking pattern BM2 may be omitted. For example, the light control layer LCL-A may include only the first blocking pattern BM1 or only the second blocking pattern BM2.

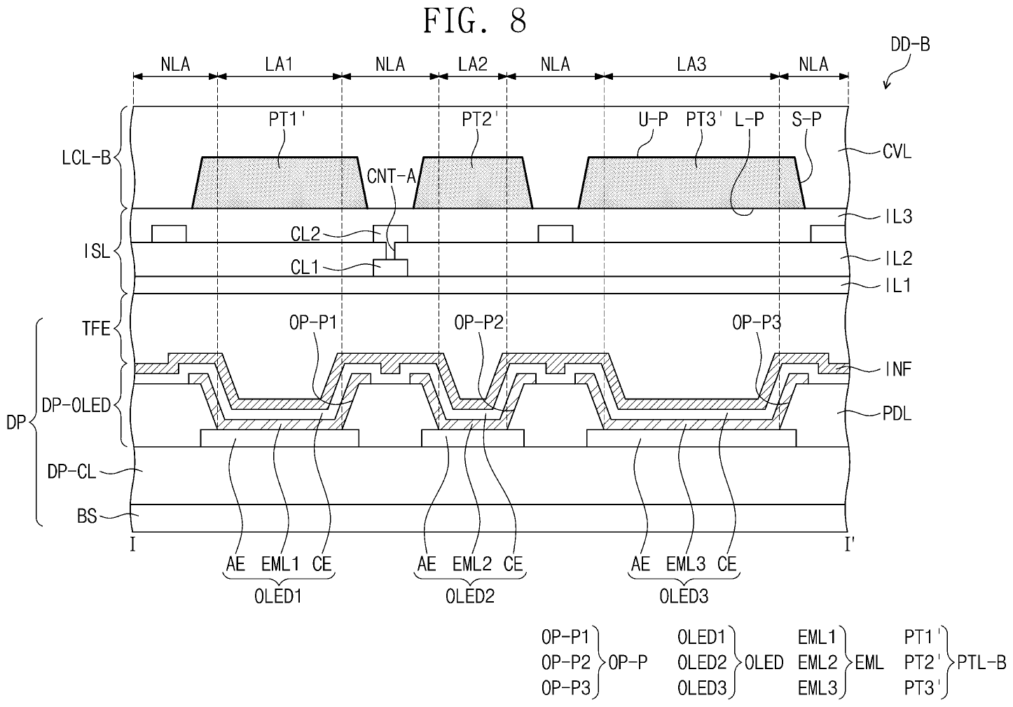

FIG. 8 is a partial cross-sectional view of a display device according to an embodiment of the present inventive concept.

According to this embodiment, the display device DD-B may include a display panel DP, an input sensor ISL, and a light control layer LCL-B, and the light control layer LCL-B may include a pattern layer PTL-B and a cover layer CVL. Same/similar reference numerals will be used for the same/similar components as those described in FIGS. 1 to 6, and duplicate descriptions may be omitted.

The pattern layer PTL-B according to this embodiment may be formed through, for example, a plasma process or an extreme ultraviolet (EUV) process. Accordingly, a polymer material included in the pattern layer PTL-B may have a relatively high degree of hardness, and the pattern layer PTL-B may have a higher mechanical strength after the plasma process or the extreme ultraviolet process than before the processes.

Therefore, according to this embodiment, since each of the first to third patterns PT1′, PT2′, and PT3′ has a relatively high degree of hardness and a relatively high strength or rigidity, process errors which may occur in each of the first to third patterns PT1′, PT2′, and PT3′ may be reduced during a subsequent step of forming the cover layer CVL.

For example, since each of the first to third patterns PT1′, PT2′, and PT3′ has a relatively high degree of hardness, a phenomenon in which the polymer material included in the first to third patterns is swelled or lifted may be prevented during the subsequent step of forming the cover layer CVL.

Accordingly, due to the pattern layer PTL-B according to this embodiment, it is possible to reduce a deviation, which may be caused by a process error of each of the first to third distances d1, d2, and d3 described with reference to FIG. 5D, and provide the light control layer LCL-B with increased reliability and a high process yield.

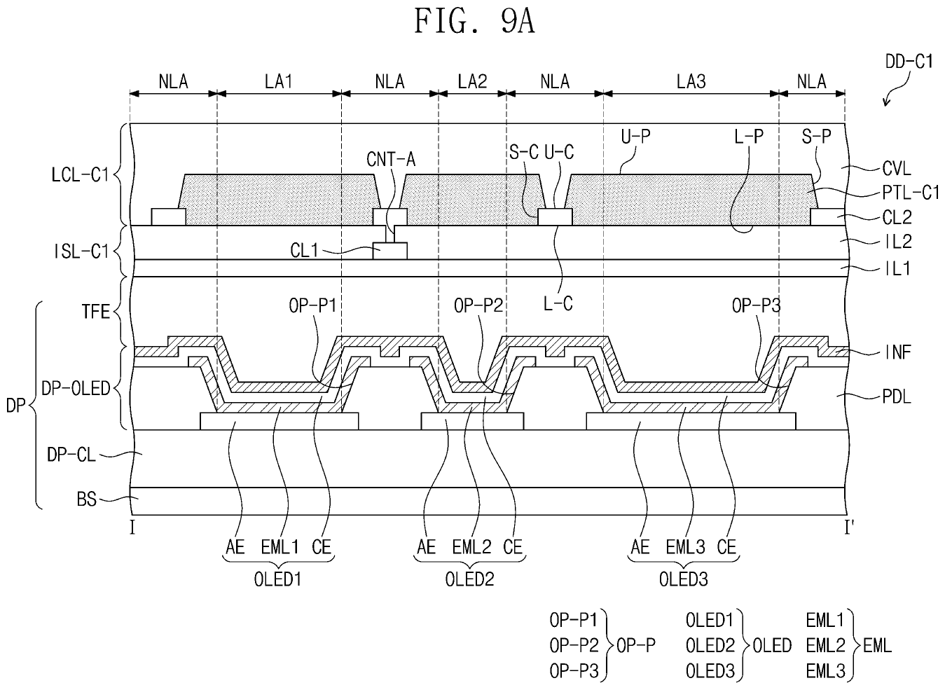

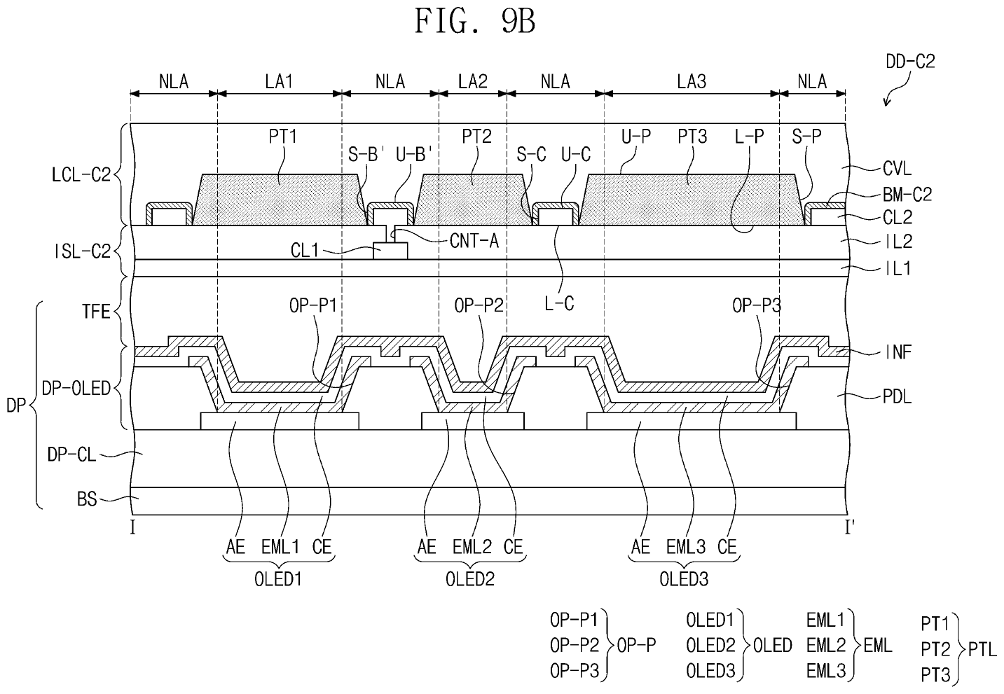

FIG. 9A is a partial cross-sectional view of a display device according to an embodiment of the present inventive concept. FIG. 9B is a partial cross-sectional view of a display device according to an embodiment of the present inventive concept.

Referring to FIG. 9A, the display device DD-C1 according to this embodiment may include a display panel DP, an input sensor ISL-C1, and a light control layer LCL-C1. In FIG. 9A, the illustration of a window adhesive layer ADL and a window WM is omitted. Same/similar reference numerals will be used for the same/similar components as those described in FIGS. 1 to 6, and duplicate descriptions may be omitted.

The input sensor ISL-C1 according to this embodiment may include a first insulating layer IL1, a first conductive layer CL1, a second insulating layer IL2, and a second conductive layer CL2. The first insulating layer IL1 may be disposed on the encapsulation layer TFE, and the first conductive layer CL1 may be disposed on the first insulating layer IL1. The second insulating layer IL2 may be disposed on the first insulating layer IL1 and may cover the first conductive layer CL1.

The second conductive layer CL2 may be disposed on the second insulating layer IL2. The second conductive layer CL2 includes a lower surface L-C, an upper surface U-C, and a side surface S-C. The lower surface L-C may be disposed on the second insulating layer IL2. For example, the lower surface L-C may be in contact with the second insulating layer IL2. The upper surface U-C may be opposite to the lower surface L-C, and the side surface S-C may connect the lower surface L-C and the upper surface U-C to each other. The second conductive layer CL2 may be electrically connected to the first conductive layer CL1 through a contact hole CNT-A formed through the second insulating layer IL2.

The light control layer LCL-C1 according to this embodiment may include a pattern layer PTL-C1 and a cover layer CVL.

The pattern layer PTL-C1 may be disposed on the second insulating layer IL2. The pattern layer PTL-C1 may cover at least a portion of the second conductive layer CL2. For example, the pattern layer PTL-C1 may cover an end portion of the second conductive layer CL2. For example, the pattern layer PTL-C1 may come in contact with the side surface S-C of the second conductive layer CL2 and may come in contact with a portion adjacent to the end of the upper surface U-C of the second conductive layer CL2.

Referring to FIG. 9B, the display device DD-C2 according to this embodiment may include a display panel DP, an input sensor ISL-C2, and a light control layer LCL-C2. In FIG. 9B, the illustration of a window adhesive layer ADL and a window WM is omitted. Same/similar reference numerals will be used for the same/similar components as those described in FIGS. 1 to 6, and duplicate descriptions may be omitted.

The light control layer LCL-C2 according to this embodiment may include a pattern layer PTL, a light blocking pattern BM-C2, and a cover layer CVL.

The pattern layer PTL may be disposed on the second insulating layer IL2. For example, the lower surface L-P of each of the first to third patterns PT1, PT2, and PT3 may come in contact with the second insulating layer IL2.

The light blocking pattern BM-C2 may be disposed on the second insulating layer IL2 and may cover the second conductive layer CL2. The second conductive layer CL2 may include a lower surface L-C (refer to FIG. 9A), an upper surface U-C. and a side surface S-C. The lower surface L-C may be in contact with the second insulating layer IL2. The upper surface U-C (refer to FIG. 9A) is opposite to the lower surface L-C, and the side surface S-C (refer to FIG. 9A) connects the lower surface L-C and the upper surface U-C to each other. According to this embodiment, the light blocking pattern BM-C2 may come in contact with the top surface U-C and the side surface S-C of the second conductive layer CL2 and cover the second conductive layer CL2.

The cover layer CVL may be disposed on the pattern layer PIT and the light blocking pattern BM-C2. According to this embodiment, the cover layer CVL may come in contact with the upper surface U-P and the side surface S-P of the pattern layer PTL and the upper surface U-B′ and the side surface S-B′ of the light blocking pattern BM-C2 and cover the pattern layer PTL and the light blocking pattern BM-C2.

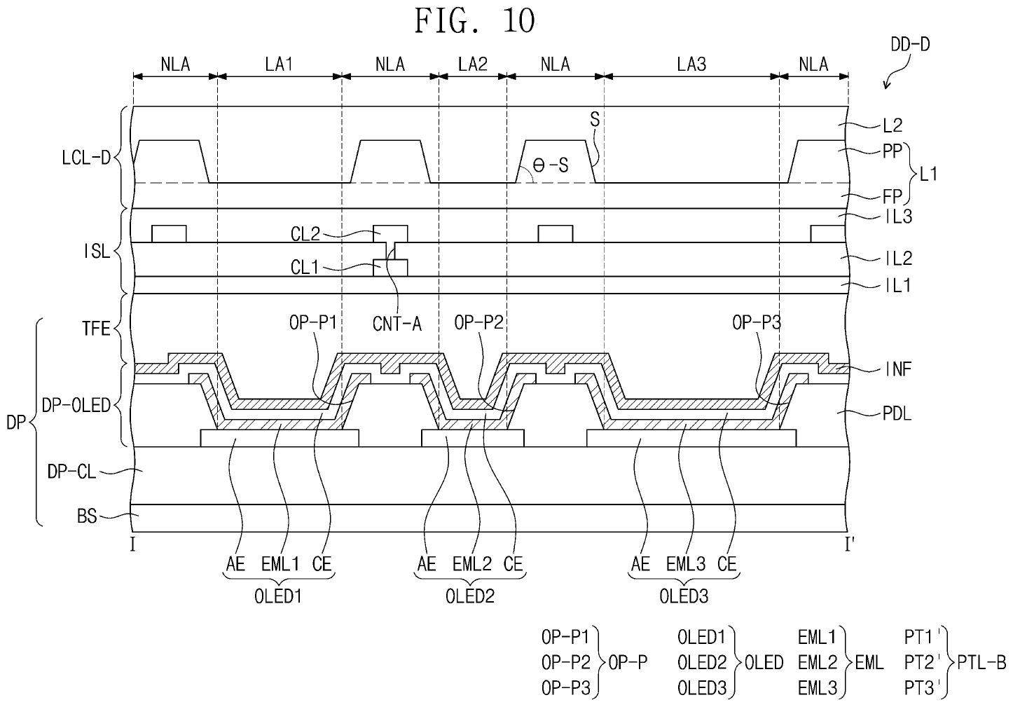

FIG. 10 is a partial cross-sectional view of a display device according to an embodiment of the present inventive concept.

Referring to FIG. 10, the display device DD-D according to this embodiment may include a display panel DP, an input sensor ISL, and a light control layer LCL-D. In FIG. 10, the illustration of a window adhesive layer ADL and a window WM is omitted. Same/similar reference numerals will be used for the same/similar components as those described in FIGS. 1 to 6, and duplicate descriptions may be omitted.

The light control layer LCL-D according to this embodiment may include a first layer L1 and a second layer L2.

The first layer L1 may be disposed on the input sensor ISL.

According to this embodiment, the first layer L1 may include a flat portion FP and a protruding portion PP disposed on the flat portion FP. The protruding portion PP may overlap the non-light-emitting region NLA. The flat portion FP and the protruding portion PP of the first layer L1 are patterned as one component or single body, but for the convenience of description, they are divided into two layers.

A side surface S of the protruding portion PP extends from the flat portion FP and may form a predetermined angle θ-S with respect to the flat portion FP. The predetermined angle θ-S may be an acute angle.

The first layer L1 may be a layer in which a dye and/or a pigment are dispersed in a polymer resin. The dye and the pigment included in the first layer L1 may be materials that transmit only light in a specific wavelength range among the light emitted from the light-emitting elements OLED1, OLED2, and OLED3. In an embodiment of the present inventive concept, the dye and pigment may be a layer that absorbs light in a wavelength range of about 490 nm to about 505 nm and light in a wavelength range of about 585 nm to about 600 nm and transmits the remaining light.

The second layer L2 may be disposed on the first layer L1 and may cover the first layer L1.

The second layer L2 may include a polymer material. The second layer L2 may include a high refractive monomer. For example, the second layer L2 may include an acrylic resin. The second layer L2 may further include nanoparticles.

According to this embodiment, the refractive index of the second layer L2 may be greater than that of the first layer L1. For example, the refractive index of the first layer L1 may be about 1.53 or less. The refractive index of the second layer L2 may be greater than or equal to about 1.6.

Accordingly, light that travels in the side direction among the light generated by the light-emitting element OLED may be reflected on the side surface S of the protruding portion PP of the first layer L1, and the path of light may be changed so that the light traveling in the side direction travels in the front direction. Accordingly, the light emission efficiency of each of the light emitting elements OLED in the front direction may be increased, and the light emission efficiency of the display panel DP including the light emitting element OLED may be increased.

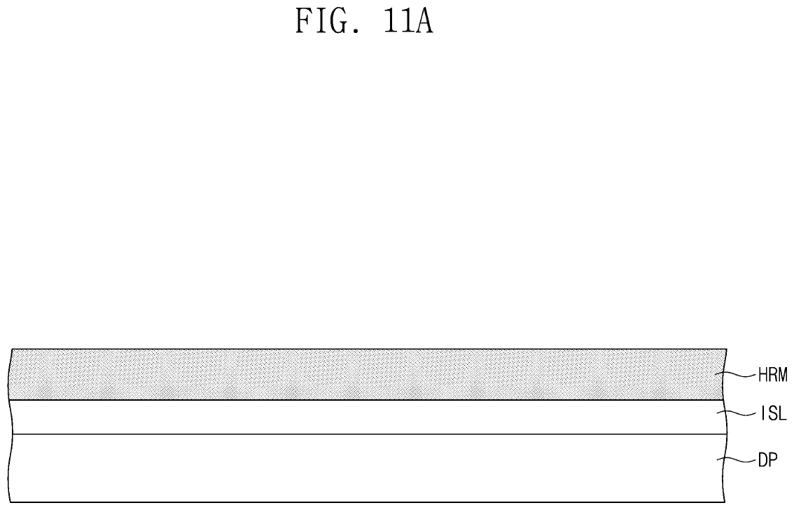

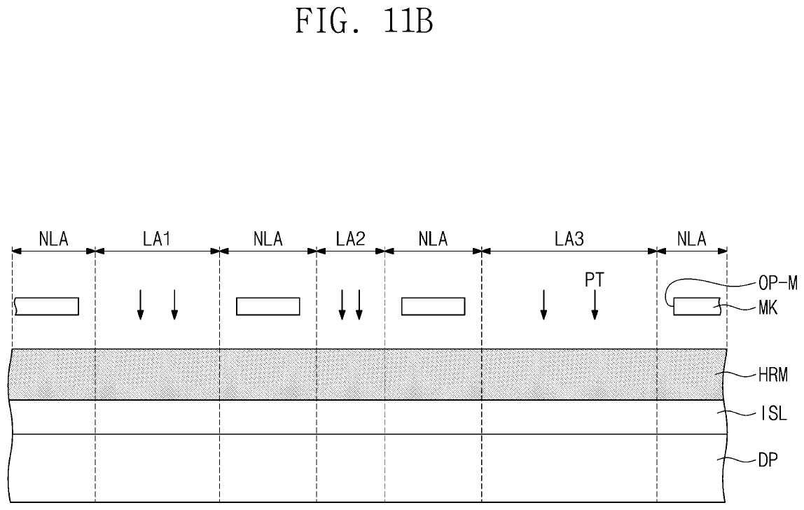

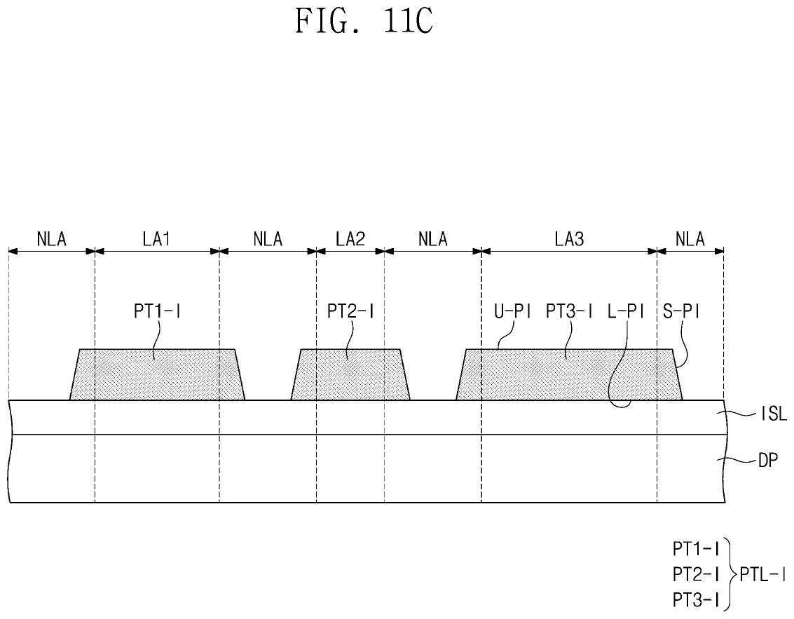

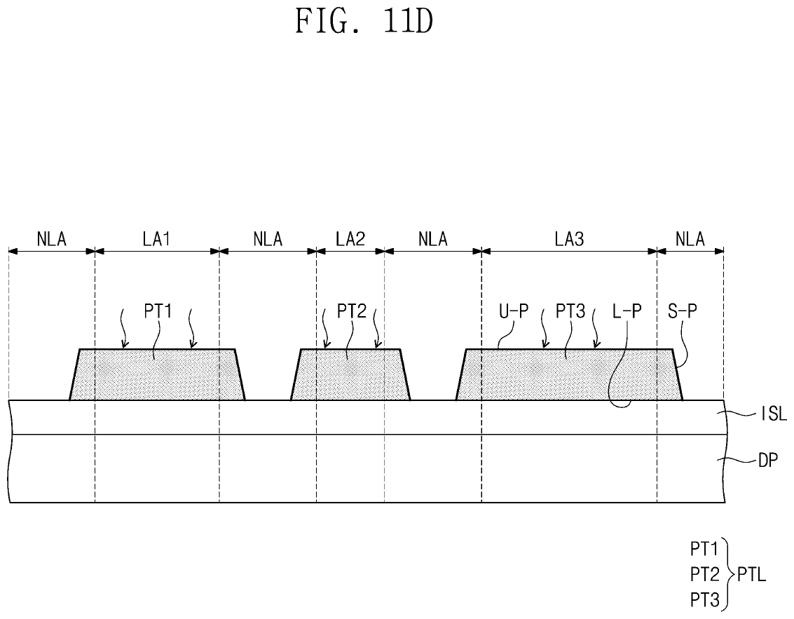

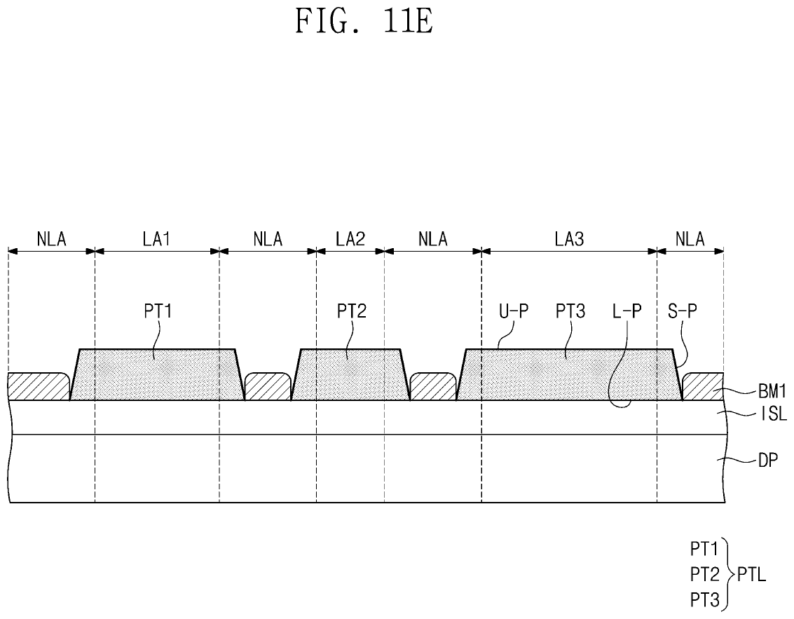

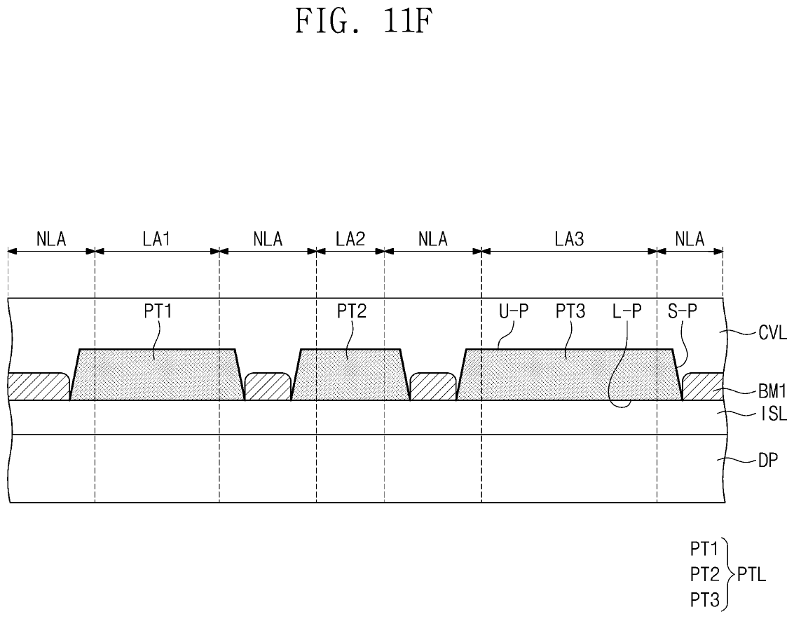

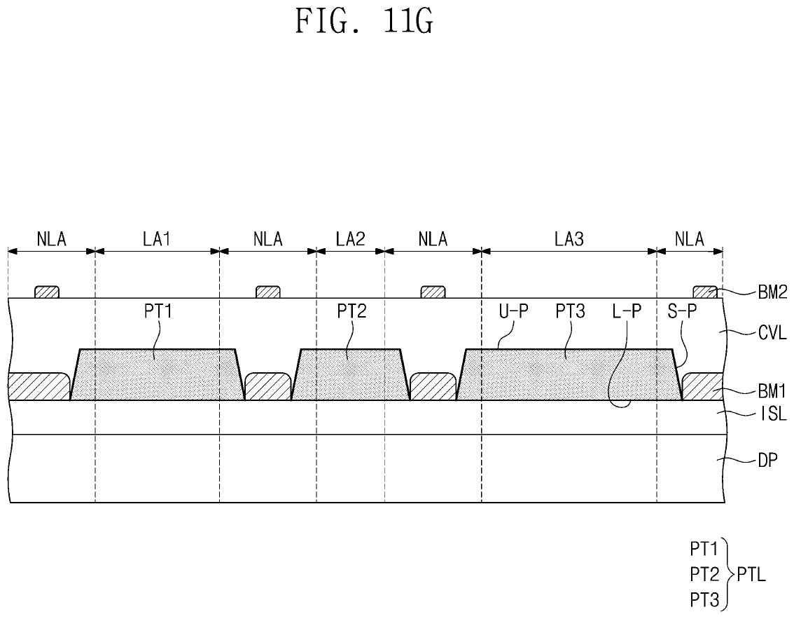

FIGS. 11A to 11G are cross-sectional views illustrating a method of manufacturing a display device according to an embodiment of the present inventive concept. Hereinafter, in describing a method of manufacturing the display device DD (refer to FIG. 1) according to an embodiment of the present inventive concept with reference to FIGS. 11A to 11G, same/similar reference numerals will be used for the same/similar components as those described in FIGS. 1 to 9B, and duplicate descriptions may be omitted. In FIGS. 11A to 11G, each of the display panel DP and the input sensor ISL is briefly illustrated as a single layer.

Referring to FIGS. 11A to 11C, the method of manufacturing the display device DD (refer to FIG. 1) according to an embodiment of the present inventive concept may include forming a pre-patterned layer PTL-I above the display panel DP.

First, referring to FIG. 11A, the forming of the pre-patterned layer PTL-I (refer to FIG. 11C) above the display panel DP may include coating a high refractive material HRM above the display panel DP. According to this embodiment, the high refractive material HRM may be a polymer material. The high refractive material HRM may include a relatively high refractive monomer.

Thereafter, referring to FIG. 11B, the forming of the pre-patterned layer PTL-I (refer to FIG. 11C) above the display panel DP may include disposing a mask MK on the coated high refractive material HRM and then irradiating the coated high refractive material HRM with light PT.

Since the high refractive material HRM has negative resist properties, a portion of the high refractive material HRM exposed to light may be cured and a portion thereof not exposed to light may be removed. The mask MK used for this purpose may include openings OP-M overlapping the pre-patterned layer PTL-I (refer to FIG. 11C) that are to be formed on the high refractive material HRM.

Thereafter, referring to FIG. 11C, the method of manufacturing the display device DD (refer to FIG. 1) according to an embodiment of the present inventive concept may include removing portions not irradiated with light PT (refer to FIG. 11B) and patterning the high refractive material HRM (refer to FIG. 11B) through a development process.

According to an embodiment of the present inventive concept, a developer used in the process of developing the high refractive material HRM may be tetramethylammonium hydroxide (TMAH). Since the TMAH solution has a low reactivity with a metal material (e.g., Al), wirings disposed in the input sensor ISL might not be damaged in the process of developing the high refractive material HRM.

A portion of the high refractive material HRM (refer to FIG. 11B) is removed so that the pre-patterned layer PTL-I including a plurality of pre-patterns PT1-I, PT2-I, and PT3-I spaced apart from each other may be formed. The pre-patterned layer PTL-I may include a first pre-pattern PT1-I formed to overlap the first light-emitting region LA1, a second pre-pattern PT2-I formed to overlap the second light-emitting region LA2, and a third pre-pattern PT3-I formed to overlap the third light-emitting region LA3.

The pre-patterned layer PTL-I may include an upper surface U-PI, a lower surface L-PI, which is opposite to the upper surface U-PI and closer to the display panel DP than the upper surface U-PI, and a side surface S-PI connecting the lower surface L-PI and the upper surface U-PI to each other. The pre-patterned layer PTL-I may be formed so that the lower surface L-PI and the side surface S-PI of the pre-patterned layer PTL-I form an acute angle.

Referring to FIG. 11D, the method of manufacturing the display device DD (refer to FIG. 1) according to an embodiment of the present inventive concept may include performing any one of a plasma process and an extreme ultraviolet (EUV) process on the pre-patterned layer PTL-I. In this case, the degree of hardness of the polymer material included in the pre-patterned layer PTL-I may be increased, thus forming a pattern layer PTL having an increased hardness, which is higher than that of the pre-patterned layer PTL-I.

The formed pattern layer PTL may include a plurality of patterns PT1, PT2, and PT3. The patterns PT1, PT2, and PT3 may include a first pattern PT1 formed to overlap the first light-emitting region LA1, a second pattern PT2 formed to overlap the second light-emitting region LA2, and a third pattern PT3 formed to overlap the third light-emitting region LA3.

The pattern layer PTL may include an upper surface U-P, a lower surface L-P, which is opposite to the upper surface U-P and closer to the display panel DP than the upper surface U-P, and a side surface SP connecting the upper surface U-P and the lower surface L-P to each other. The pattern layer PTL may be formed so that the lower surface L-P and the side surface S-P of the pattern layer PTL form an acute angle.

According to an embodiment of the present inventive concept, the plasma process step or the extreme ultraviolet (EUV) process step may be omitted.

Referring to FIG. 11E, the method of manufacturing the display device DD (refer to FIG. 1) according to an embodiment of the present inventive concept may include forming the first light blocking pattern BM1.

The forming of the first light blocking pattern BM1 may include: coating the display panel DP with a light blocking material to cover the pattern layer PTL; disposing a mask on the coated light blocking material and emitting light; and forming the first light blocking pattern BM1 patterned by developing the light blocking material exposed to light.

According to this embodiment, the first blocking pattern BM1 may be formed to overlap the non-light-emitting region NLA. For example, the first blocking pattern BM1 may be formed to overlap the pixel defining film PDL (refer to FIG. 4B) of the display panel DP. In addition, the first blocking pattern BM1 may be formed to at least partially surround the first to third patterns PT1, PT2, and PT3 on a plane.

According to an embodiment of the present inventive concept, the forming of the first blocking pattern BM1 may be performed before the forming of the pattern layer PTL

Referring to FIG. 11F, the method of manufacturing the display device DD (refer to FIG. 1) according to an embodiment of the present inventive concept may include forming a cover layer CVL. The cover layer CVL may be formed to cover the pattern layer PTL. For example, the cover layer CVL may come in contact with the upper surface U-P and the side surface S-P of the pattern layer PTL and cover the pattern layer PTL.

The cover layer CVL may include a polymer material and a dye and/or a pigment dispersed in the polymer material. According to this embodiment, the cover layer CVL may have a lower refractive index than that of the pattern layer PTL.

The cover layer CVL may be patterned and formed in units of cells on the basis of one display device DD (refer to FIG. 1) through a photolithography process, and the cover layer CVL may be provided by being patterned by an inkjet printing method.

When the cover layer CVL is formed by a photolithography process, a developer used in the development process of the cover layer CVL may be potassium hydroxide (KOH). Since the KOH solution has a low reactivity with a metal material (e.g., Al), wirings disposed in the input sensor ISL might not be damaged in the process of developing the cover layer CVL.

Referring to FIG. 11G, the method of manufacturing the display device DD (refer to FIG. 1) according to an embodiment of the present inventive concept may include forming a second light blocking pattern BM2 on the cover layer CVL.

The forming of the second light blocking pattern BM2 may include: coating the cover layer CVL with a light blocking material; disposing a mask on the coated light blocking material and emitting light; and forming the second light blocking pattern BM2 that is patterned by developing the light blocking material exposed to light.

According to this embodiment, the second blocking pattern BM2 may be formed to overlap the non-light-emitting region NLA. According to an embodiment of the present inventive concept, the second light blocking pattern BM2 may be formed to have a smaller width than that of the first light blocking pattern BM1.

At least any one of forming the first light blocking pattern BM1 or forming the second light blocking pattern BM2 may be omitted.

According to the present inventive concept, the light control layer may include a pattern layer having a relatively high refractive index and a cover layer covering the pattern layer and having a relatively low refractive index, thus increasing light efficiency. In addition, the reflection of external light may be reduced by matching the refractive indices of the cover layer of the light control layer and the window adhesive layer disposed on the cover layer.

According to the present inventive concept, although the light control layer does not include a color filter, light efficiency may be increased and the reflection of external light may be reduced. Therefore, the manufacturing process of the light control layer may be simplified and it is possible to provide a display device with reduced manufacturing time and manufacturing cost.

While the present inventive concept has been described with reference to embodiments thereof, it will be understood by those of ordinary skill in the art that various changes in form and details may be made thereto without departing from the spirit and scope of the present inventive concept.

What is claimed is:

1. A display device comprising:
a display panel comprising a pixel defining film and a light-emitting element, wherein the pixel defining film includes a pixel opening, wherein the light-emitting element comprises a first electrode, a light-emitting layer, and a second electrode, and wherein the first electrode is at least partially exposed through the pixel opening; and
a light control layer comprising a pattern layer and a cover layer, wherein the pattern layer overlaps the pixel opening, and wherein the cover layer covers the pattern layer and has a refractive index lower than that of the pattern layer,
wherein:
the pattern layer comprises an upper surface, a lower surface opposite to the upper surface and more adjacent to the display panel than the upper surface, and a side surface connecting the upper surface and the lower surface to each other, and
an angle between the side surface and the lower surface is an acute angle.

2. The display device of claim 1, wherein, at a portion of the pattern layer at which a thickness from the lower surface to the side surface of the pattern layer is about ⅓ of a maximum thickness of the pattern layer, and wherein the angle formed by the lower surface with respect to a tangential direction of the side surface is about 65 degrees or less.

3. The display device of claim 1, wherein a maximum thickness of the pattern layer is about 1.5 micrometers to about 3.5 micrometers.

4. The display device of claim 1, wherein:
the pixel opening comprises a first pixel opening, a second pixel opening, and a third pixel opening which have different areas from each other, and
the pattern layer comprises a first pattern corresponding to the first pixel opening, a second pattern corresponding to the second pixel opening, and a third pattern corresponding to the third pixel opening.

5. The display device of claim 4, wherein, on a plane, a distance between an edge of each of the first to third patterns and an edge of a corresponding pixel opening among the first to third pixel openings is about 0.5 micrometers or more.

6. The display device of claim 4, wherein, on a plane, a distance between an edge of the first pattern and an edge of the first pixel opening, a distance between an edge of the second pattern and an edge of the second pixel opening, and a distance between an edge of the third pattern and an edge of the third pixel are different from one another.

7. The display device of claim 1, further comprising an input sensor disposed between the display panel and the light control layer,
wherein the display panel further comprises an encapsulation layer disposed on the light-emitting element,
wherein the input sensor comprises a first insulating layer, a first conductive layer, a second insulating layer, a second conductive layer, and a third insulating layer, wherein the first insulating layer is disposed on the encapsulation layer, wherein the first conductive layer is disposed on the first insulating layer, wherein the second insulating layer is disposed on the first insulating layer and covers the first conductive layer, wherein the second conductive layer is disposed on the second insulating layer, and wherein the third insulating layer is disposed on the second insulating layer and covers the second conductive layer, and
wherein the light control layer is disposed on the third insulating layer.

8. The display device of claim 1, further comprising an input sensor disposed between the display panel and the light control layer,
wherein the display panel further comprises an encapsulation layer disposed on the light-emitting element,
wherein the input sensor comprises a first insulating layer, a first conductive layer, a second insulating layer, and a second conductive layer, wherein the first insulating layer is disposed on the encapsulation layer, wherein the first conductive layer is disposed on the first insulating layer, wherein the second insulating layer is disposed on the first insulating layer and covers the first conductive layer, and wherein the second conductive layer is disposed on the second insulating layer, and
wherein the light control layer is disposed on the second insulating layer.

9. The display device of claim 8, wherein the pattern layer covers at least a portion of the second conductive layer.

10. The display device of claim 8, wherein the light control layer further comprises a light blocking pattern covering the second conductive layer.

11. The display device of claim 1, further comprising a light blocking pattern disposed at least between the display panel and the cover layer or on an upper surface of the cover layer, wherein the light blocking pattern overlaps the pixel defining film.

12. The display device of claim 1, further comprising:
a first light blocking pattern disposed between the display panel and the cover layer and comprising a first light blocking opening overlapping the pixel opening; and
a second light blocking pattern disposed on the cover layer and comprising a second light blocking opening overlapping the pixel opening,
wherein an area of the second light blocking opening is larger than an area of the first light blocking opening.

13. The display device of claim 1, wherein:
the refractive index of the cover layer is about 1.53 or less; and
the refractive index of the pattern layer is about 1.6 or more.

14. The display device of claim 1, wherein:
each of the cover layer and the pattern layer comprises a polymer material, and
the cover layer further comprises at least one of a pigment or a dye dispersed in the polymer material.

15. The display device of claim 1, wherein:
the display panel further comprises a first capping layer, a second capping layer, and an encapsulation layer, wherein the first capping layer is disposed on the second electrode, wherein the second capping layer is disposed on the first capping layer, and wherein the encapsulation layer is disposed on the second capping layer,
wherein each of the first capping layer and the second capping layer comprises an inorganic material, and
wherein the second capping layer comprises at least one of ytterbium, bismuth, or an alloy.

16. A display device comprising:
a display panel comprising a pixel defining film and a light-emitting element, wherein the pixel defining film comprises a pixel opening, and wherein the light-emitting element comprises a first electrode, a light-emitting layer, and a second electrode, wherein the first electrode is at least partially exposed through the pixel opening;
a light control layer comprising a pattern layer and a cover layer, wherein the pattern layer overlaps the pixel opening, and wherein the cover layer covers the pattern layer and has a refractive index lower than that of the pattern layer;
a window disposed on the light control layer; and
a window adhesive layer disposed between the light control layer and the window to couple the light control layer and the window to each other,
wherein the difference in refractive indices between the cover layer and the window is about 0.1 or less.

17. The display device of claim 16, wherein:
the refractive index of the cover layer is about 1.53 or less; and
the refractive index of the pattern layer is about 1.6 or more.

18. A method for manufacturing a display device, the method comprising:
forming a pre-patterned layer on a display panel comprising a pixel defining film and light-emitting element, wherein the pixel defining film comprises a pixel opening, wherein the light-emitting element comprises a first electrode, a light-emitting layer, and a second electrode, wherein the first electrode is at least partially exposed through the pixel opening, wherein the pre-patterned layer overlaps the pixel opening;
performing any one of a plasma process or an extreme ultraviolet process on the pre-patterned layer to form a pattern layer from the pre-patterned layer; and
forming a cover layer covering the pattern layer and having a refractive index lower than the pattern layer.

19. The method of claim 18, further comprising forming a light blocking pattern, which overlaps the pixel defining film, on the display panel.

20. The method of claim 18, wherein:
in the forming of the pre-patterned layer, the pre-patterned layer comprises an upper surface, a lower surface opposite to the upper surface and more adjacent to the display panel than the upper surface, and a side surface connecting the upper surface and the lower surface to each other, and
an angle between the side surface and the lower surface is formed to be an acute angle.
